(19) United States
(12) Patent Application Publication
(10) Pub. No.: US 2026/0314394 A1
(43) Pub. Date: Oct. 8, 2026

(54) PACKAGE STRUCTURE AND METHOD FOR FORMING THE SAME

(71) Applicant: TAIWAN SEMICONDUCTOR MANUFACTURING COMPANY, LTD., Hsinchu (TW)

(72) Inventors: Chung-Hui CHEN, Hsinchu City (TW); Cheng-Hsiang HSIEH, Taipei City (TW); Chin-Ming FU, Hsinchu County (TW)

(73) Assignee: TAIWAN SEMICONDUCTOR MANUFACTURING COMPANY, LTD., Hsinchu (TW)

(21) Appl. No.: 19/173,448

(22) Filed: Apr. 8, 2025

(51) Int. Cl. H01L 23/522; H01L 23/00; H01L 23/48; H01L 23/538; H01L 25/00; H01L 25/07; H10D 1/00; H10D 1/20; H10D 1/68

(52) U.S. Cl. CPC H10W 20/497; H10D 1/041; H10D 1/20; H10D 1/714; H10D 1/716; H10W 20/20; H10W 90/00; H10W 70/60; H10W 70/611; H10W 90/297; H10W 90/722; H10W 90/724; H10W 90/792

(57) ABSTRACT

A package structure includes a first semiconductor die, a first routing structure, a top die, a second routing structure, and a package substrate. The first semiconductor die includes a semiconductor substrate, a first transistor and a second transistor over the semiconductor substrate, a front side interconnect structure above first transistor and the second transistor, wherein the front side interconnect structure comprises a first inductor, wherein the first inductor is electrically coupled with source/drain regions of the first transistor and the second transistor, and a backside interconnect structure below the semiconductor substrate. The first routing structure is over and electrically connected to the first semiconductor die. The top die is over and electrically connected to the first routing structure. The second routing structure is below and electrically connected to the first semiconductor die. The package substrate is below and electrically connected to the second routing structure.

### BACKGROUND

Semiconductor devices and integrated circuits used in a variety of electronic apparatus, such as cell phones and other mobile electronic equipment, are typically manufactured on a single semiconductor wafer. The dies of the wafer may be processed and packaged with other semiconductor devices or dies at the wafer level, and various technologies have been developed for the wafer level packaging. How to ensure the reliability of the wafer level packaging has become a challenge in the field.

### BRIEF DESCRIPTION OF THE DRAWINGS

Aspects of the present disclosure are best understood from the following detailed description when read with the accompanying figures. It is noted that, in accordance with the standard practice in the industry, various features are not drawn to scale. In fact, the dimensions of the various features may be arbitrarily increased or reduced for clarity of discussion.

FIG. 1A is a cross-sectional view of a package structure in accordance with some embodiments.

FIG. 1B is a cross-sectional view of a package structure in accordance with some embodiments.

FIG. 1C is a circuit diagram of a semiconductor die in accordance with some embodiments.

FIG. 1D is a top view of a semiconductor die in accordance with some embodiments.

FIGS. 2 to 7 illustrate a method in various stages of forming a package structure in accordance with some embodiments of the present disclosure.

FIGS. 8 to 12 illustrate a method in various stages of forming an inductor in accordance with some embodiments of the present disclosure.

FIG. 13A is a cross-sectional view of a package structure in accordance with some embodiments.

FIG. 13B is a circuit diagram of a semiconductor die in accordance with some embodiments.

FIGS. 14 to 16 illustrate a method in various stages of forming a package structure in accordance with some embodiments of the present disclosure.

FIG. 17A is a cross-sectional view of a package structure in accordance with some embodiments.

FIG. 17B is a circuit diagram of a semiconductor die in accordance with some embodiments.

FIG. 18A is a cross-sectional view of a package structure in accordance with some embodiments.

FIG. 18B is a circuit diagram of a semiconductor die in accordance with some embodiments.

FIGS. 19 to 21 illustrate a method in various stages of forming a capacitor in accordance with some embodiments of the present disclosure.

FIG. 22A is a cross-sectional view of a package structure in accordance with some embodiments.

FIG. 22B is a circuit diagram of a semiconductor die in accordance with some embodiments.

FIG. 23 is a cross-sectional view of a package structure in accordance with some embodiments.

### DETAILED DESCRIPTION

The following disclosure provides many different embodiments, or examples, for implementing different features of the provided subject matter. Specific examples of components and arrangements are described below to simplify the present disclosure. These are, of course, merely examples and are not intended to be limiting. For example, the formation of a first feature over or on a second feature in the description that follows may include embodiments in which the first and second features are formed in direct contact, and may also include embodiments in which additional features may be formed between the first and second features, such that the first and second features may not be in direct contact. In addition, the present disclosure may repeat reference numerals and/or letters in the various examples. This repetition is for the purpose of simplicity and clarity and does not in itself dictate a relationship between the various embodiments and/or configurations discussed.

Further, spatially relative terms, such as “beneath,” “below,” “lower,” “above,” “upper” and the like, may be used herein for ease of description to describe one element or feature's relationship to another element(s) or feature(s) as illustrated in the figures. The spatially relative terms are intended to encompass different orientations of the device in use or operation in addition to the orientation depicted in the figures. The apparatus may be otherwise oriented (rotated 90 degrees or at other orientations) and the spatially relative descriptors used herein may likewise be interpreted accordingly. As used herein, “around,” “about,” “approximately,” or “substantially” may generally mean within 20 percent, or within 10 percent, or within 5 percent of a given value or range. Numerical quantities given herein are approximate, meaning that the term “around,” “about,” “approximately,” or “substantially” can be inferred if not expressly stated. One skilled in the art will realize, however, that the values or ranges recited throughout the description are merely examples, and may be reduced or varied with the down-scaling of the integrated circuits. One of ordinary skill in the art will appreciate that the dimensions may be varied according to different technology nodes. One of ordinary skill in the art will recognize that the dimensions depend upon the specific device type, technology generation, minimum feature size, and the like. It is intended, therefore, that the term be interpreted in light of the technology being evaluated.

Other features and processes may also be included. For example, testing structures may be included to aid in the verification testing of the 3D packaging or 3DIC devices. The testing structures may include, for example, test pads formed in a redistribution layer or on a substrate that allows the testing of the 3D packaging or 3DIC, the use of probes and/or probe cards, and the like. The verification testing may be performed on intermediate structures as well as the final structure. Additionally, the structures and methods disclosed herein may be used in conjunction with testing methodologies that incorporate intermediate verification of known good dies to increase the yield and decrease costs.

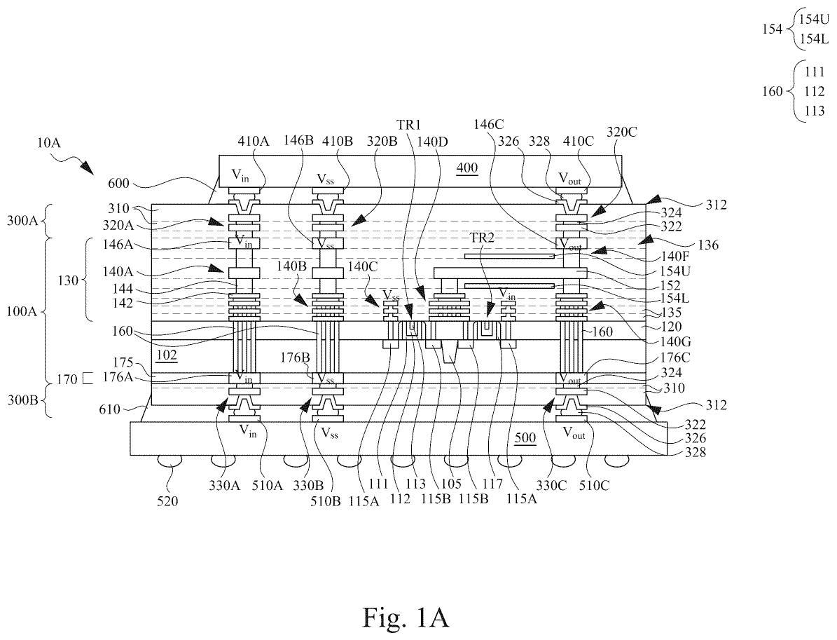

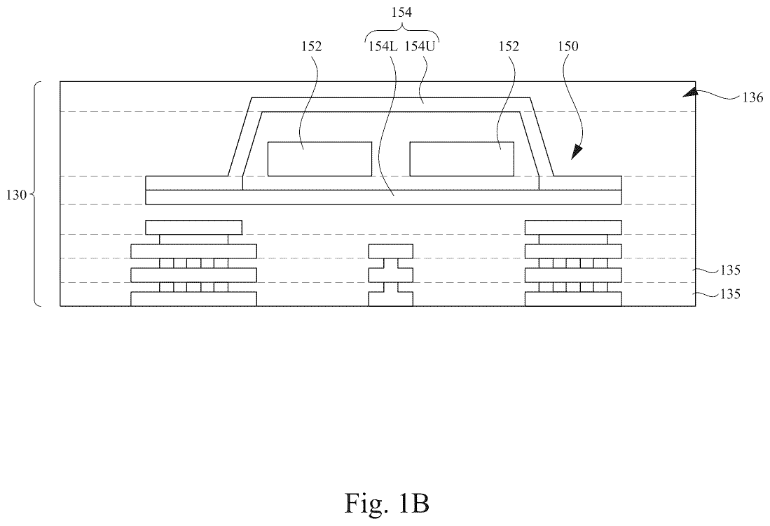

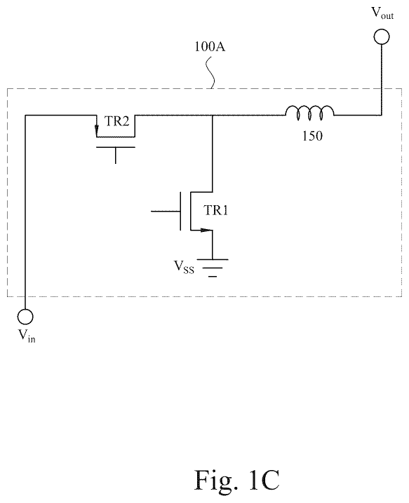

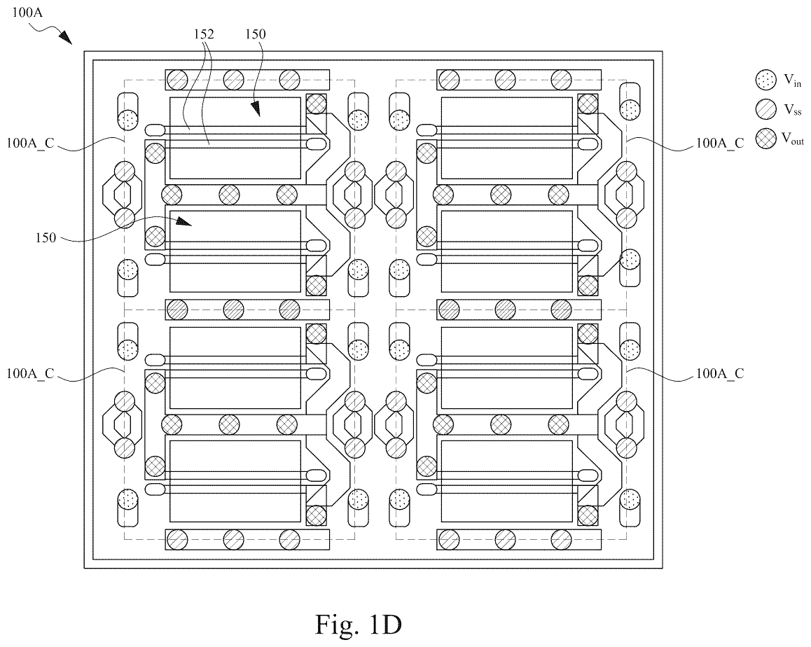

FIG. 1A is a cross-sectional view of a package structure in accordance with some embodiments. Shown there is a package structure 10A. In some embodiments, the package structure 10A is a chip on wafer on substrate (CoWoS) packaging structure. In some embodiments, the package structure 10A is a three dimensional integrated circuit (3D IC). The package structure 10A includes a semiconductor die 100A, a routing structure 300A electrically connected to a first side of the semiconductor die 100A, and a routing structure 300B electrically connected to a second side of the semiconductor die 100A that is opposite to the first side of the semiconductor die 100A. The package structure 10A further includes a semiconductor die 400 electrically connected to the routing structure 300A, and a package substrate 500 electrically connected to the routing structure 300B.

With respect to the semiconductor die 100A, in some embodiments, the semiconductor die 100A may be a coupled inductor voltage regulator (CLVR), and thus the semiconductor die 100A can also be referred to as a CLVR die.

The semiconductor die 100A includes a substrate 102. In some embodiments, the substrate 102 may be a semiconductor substrate. For example, the substrate 102 may be made of silicon or other semiconductor materials. In some embodiments, the substrate 102 is made of a compound semiconductor such as silicon carbide, gallium arsenic, indium arsenide or indium phosphide. In some embodiments, the substrate 102 is made of an alloy semiconductor such as silicon germanium, silicon germanium carbide, gallium arsenic phosphide, or gallium indium phosphide. However, the disclosure is not limited thereto. In some alternative embodiments, the substrate 102 may be a glass substrate or a polymeric substrate. For example, the substrate 102 may include epoxy, polyimide, resin, or the like. In some embodiments, the substrate 102 may be a bulk substrate without any conductive feature embedded therein.

A transistor TR1 and a transistor TR2 are disposed over the substrate 102. In some embodiments, the transistor TR1 and the transistor TR2 may include opposite conductivity types. For example, the transistor TR1 may be an N-type transistor, and the transistor TR2 maybe a P-type transistor. In some embodiments, the transistors TR1 and TR2 may be planar field effect transistor (FET), fin-type field effect transistor (FinFET), gate-all-around field effect transistor (GAAFET), complementary field effect transistor (CFET), the like, or other suitable active devices.

Each of the transistors TR1 and TR2 includes a gate structures 110, and source/drain features 115A and 115B on opposite sides of the gate structure 110. Here, the source/drain features 115A can function as source regions of the transistors TR1 and TR2, respectively. The source/drain features 115B can function as drain regions of the transistors TR1 and TR2, respectively. In some embodiments, the gate structure 110 may include a gate dielectric layer 111, a work function metal layer 112 over the gate dielectric layer 111, and a filling metal 113 over the work function metal layer 112. Gate spacers 117 are disposed on opposite sidewalls of the gate structure 110.

In some embodiments, the gate dielectric layer 111 may include an interfacial layer and a high-k dielectric layer. Exemplary interfacial layer may include oxide, such as silicon oxide (SiO₂), aluminum oxide (Al₂O₃), or the like. Examples of high-k dielectric material include HfO₂, HfSiO, HfSiON, HfTaO, HfTiO, HfZrO, zirconium oxide, titanium oxide, hafnium dioxide-alumina (HfO₂—Al₂O₃) alloy, other suitable high-k dielectric materials, and/or combinations thereof. The work function metal layer 112 may be an n-type or p-type work function layer. Exemplary p-type work function metals include TiN, TaN, Ru, Mo, Al, WN, ZrSi₂, MoSi₂, TR1 asi₂, NiSi₂, WN, other suitable p-type work function materials, or combinations thereof. Exemplary n-type work function metals include Ti, Ag, TaAl, TaAlC, TiAlN, TaC, TaCN, TR1 asiN, Mn, Zr, other suitable n-type work function materials, or combinations thereof. The work function layer may include a plurality of layers. The filling metal 113 may include tungsten (W), aluminum (Al), copper (Cu), or another suitable conductive material(s).

The source/drain features 115A and 115B may include epitaxial materials, such as silicon (Si), silicon germanium (SiGe), silicon phosphide (SiP), silicon carbide (SiC), or the like. In some embodiments, the source/drain features 115A and 115B may include n-type dopants or p-type dopants, depending on the conductivity type of the transistor. For example, the source/drain features 115A and 115B of the transistor TR1 may be doped with n-type dopants, such as phosphorus (P), arsenic (As), or antimony (Sb), or the like. On the other hand, the source/drain features 115 of the transistor TR2 may be doped with p-type dopants, such as boron (B), gallium (Ga), indium (In), aluminium (Al), or the like. In some embodiments, the gate spacers 117 may be formed of silicon oxide, silicon nitride, silicon oxynitride, the like, or combinations thereof.

In some embodiments, a shallow trench isolation (STI) structure 105 may be disposed in the substrate 102 and located at a position between the transistors TR1 and TR2, so as to provide electrical isolation between the transistors TR1 and TR2. In some embodiments, the STI structure 105 may be made of oxide (e.g., silicon oxide), nitride (e.g., silicon nitride), or combinations thereof.

An interlayer dielectric (ILD) layer 120 is disposed over the substrate 102 and laterally surrounding the gate structures 110 of the transistors TR1 and TR2. In some embodiments, the ILD layer 120 may include silicon oxide, silicon nitride, silicon oxynitride, tetraethoxysilane (TEOS), phosphosilicate glass (PSG), borophosphosilicate glass (BPSG), low-k dielectric material, and/or other suitable dielectric materials. Examples of low-k dielectric materials include, but are not limited to, fluorinated silica glass (FSG), carbon doped silicon oxide, amorphous fluorinated carbon, parylene, bis-benzocyclobutenes (BCB), or polyimide.

Contacts 118 are disposed in the ILD layer 120 and electrically connected to the source/drain features 115A and 115B, respectively. The contacts 118 can also be referred to as source/drain contacts 118. In some embodiments, the source/drain contacts 118 each may include a conductive material and a liner lining the conductive material. The liner may include titanium, titanium nitride, tantalum, tantalum nitride, or the like. The conductive material may be copper, a copper alloy, silver, gold, tungsten, cobalt, aluminum, nickel, or the like.

An interconnect structure 130 is disposed over the interlayer dielectric (ILD) layer 120. In some embodiments, the interconnect structure 130 is disposed on the front side of the substrate 102, and thus the interconnect structure 130 can also be referred to as a front side interconnect structure. In some embodiments, the interconnect structure 130 may include several dielectric layers 135 stacking one above another. According to some embodiments, the dielectric layers 135 are made of one or more suitable dielectric materials such as an oxide (e.g., silicon oxide), a nitride (e.g., silicon nitride), a polymer material, a polyimide material, a low-k dielectric material, another dielectric material, the like, or a combination thereof. In some embodiments, some or all of the dielectric layers 135 may comprise the same insulating materials and/or some of the dielectric layers 135 may comprise different insulating materials from the other layers. In some embodiments, the dielectric layers 135 can be collectively referred to as a dielectric structure 136.

The interconnect structure 130 further includes several conductive structures 140A, 140B, 140C, 140D, 140F, and 140G disposed in the dielectric structure 136 formed by the dielectric layers 135. In some embodiments, each of the conductive structures 140A, 140B, 140C, 140D, 140F, and 140G may include several metal lines 142 and metal vias 144 coupled with the respective metal lines 142. In some embodiments, each of the metal lines 142 is laterally extended within the respective dielectric layer 135, while each of the metal vias 144 is vertically extended within the respective dielectric layer 135. In some embodiments, the metal lines 142 and metal vias 144 are stacked alternately within the dielectric structure 136 formed by dielectric layers 135.

The interconnect structure 130 further includes an inductor 150 within the dielectric structure 136. In some embodiments, the inductor 150 includes one or more conductors 152, and a magnetic layer 154 surrounding and/or enclosing the one or more conductors 152 (see FIG. 1B). In some embodiments, the conductors 152 are spaced apart from the magnetic layer 154 through a material of the dielectric structure 136. In some embodiments, the magnetic layer 154 includes a lower magnetic layer 154L and an upper magnetic layer 154U over the lower magnetic layer 154L. In the cross-sectional view of FIG. 1A, the upper magnetic layer 154U is above the one or more conductors 152, and the lower magnetic layer 154L is below the one or more conductors 152. The inductor 150 may vertically overlap the transistor TR2, while in other embodiments the inductor 150 may vertically overlap both the transistors TR1 and TR2. In some embodiments, the conductors 152 may include a same material as the conductive structures 140A to 140G, such as such as copper, gold, silver, and/or the like. The magnetic layer 154 may be formed of one or more magnetic materials, such as a cobalt alloy (e.g., cobalt-zirconium-tantalum (CoZrTa) and/or the like), a nickel alloy (e.g., nickel-iron (NiFe) and/or the like), and/or another magnetic material.

Reference is made to FIG. 1B, in which FIG. 1B is a cross-sectional view of the interconnect structure 130. Here, the cross-sectional view of FIG. 1B is perpendicular to the cross-sectional view of FIG. 1A to show the inductor 150 from different view. In FIG. 1B, shown there is a pair of conductors 152 surrounded by the magnetic layer 154. It is understood that the number of the conductors 152 can be varied in different embodiments. On the other hand, in the cross-sectional view of FIG. 1B, the upper magnetic layer 154U may be in contact with opposite ends of the lower magnetic layer 154L to form a ring-shape cross-sectional profile that surrounds the conductors 152.

Referring back to the interconnect structure 130 of FIG. 1A, with respect to the conductive structures 140A, the conductive structure 140A further includes a metal pad 146A exposed through top surface of the dielectric structure 136 of the interconnect structure 130. In some embodiments, top surface of the metal pad 146A may be substantially level with top surface of the topmost dielectric layer 135 of the dielectric structure 136. In some embodiments, the metal pad 146A serves as an input terminal Vᵢₙ of the semiconductor die 100A.

With respect to the conductive structures 140B, the conductive structure 140B further includes a metal pad 146B exposed through top surface of the dielectric structure 136 of the interconnect structure 130. In some embodiments, top surface of the metal pad 146B may be substantially level with top surface of the topmost dielectric layer 135 of the dielectric structure 136. In some embodiments, the metal pad 146B serves as a ground terminal Vₛₛ of the semiconductor die 100A.

With respect to the conductive structure 140C, the conductive structure 140C is electrically connected with the source/drain feature 115A of the transistor TR1 through the respective source/drain contact 118. In some embodiments, the conductive structure 140C may be electrically connected to the conductive structure 140B through other conductive structure (not shown) in the interconnect structure 130. As a result, the source/drain feature 115A of the transistor TR1 can be electrically connected to the metal pad 146B (e.g., ground terminal Vₛₛ).

With respect to the conductive structure 140D, the conductive structure 140D is electrically connected to the source/drain feature 115B of the transistors TR1 and TR2 through the respective source/drain contacts 118, and is electrically connected to a first end of the one or more conductors 152 of the inductor 150. Accordingly, the source/drain features 115B of the transistors TR1 and TR2 may be electrically connected to the first end of the one or more conductors 152 of the inductor 150.

With respect to the conductive structure 140E, the conductive structure 140E is electrically connected with the source/drain feature 115A of the transistor TR2 through the respective source/drain contact 118. In some embodiments, the conductive structure 140E may be electrically connected to the conductive structure 140A through other conductive structure (not shown) in the interconnect structure 130. As a result, the source/drain feature 115A of the transistor TR2 can be electrically connected to the metal pad 146A (e.g., input terminal Vᵢₙ).

With respect to the conductive structure 140F, the conductive structure 140E is electrically connected with a second end of the one or more conductors 152 of the inductor 150 that is opposite to the first end of the one or more conductors 152 of the inductor 150. The conductive structure 140F further includes a metal pad 146F exposed through top surface of the dielectric structure 136 of the interconnect structure 130. In some embodiments, top surface of the metal pad 146F may be substantially level with top surface of the topmost dielectric layer 135 of the dielectric structure 136. In some embodiments, the metal pad 146F serves as an output terminal Vₒᵤₜ of the semiconductor die 100A.

With respect to the conductive structure 140G, the conductive structure 140E is electrically connected with the second end of the one or more conductors 152 of the inductor 150. In greater detail, the conductive structure 140G is in contact with bottom surface of the second end of the one or more conductors 152 of the inductor 150, and the conductive structure 140F is in contact with top surface of the second end of the one or more conductors 152 of the inductor 150. Accordingly, the conductive structure 140F and conductive structure 140G are electrically connected with each other through the one or more conductors 152 of the inductor 150.

The semiconductor die 100A further includes conductive vias 160 extending through the substrate 102 and electrically connected to the conductive structures 140A, 140B, and 140G, respectively. In some embodiments, the conductive vias 160 may also extend to the ILD layer 120. The conductive vias 160 may include conductive material, such as such as copper, gold, silver, and/or the like. In some embodiments, the conductive vias 160 can also be referred to as through-silicon-vias (TSVs).

The semiconductor die 100A further includes an interconnect structure 170 in contact with bottom surface of the substrate 102. In some embodiments, the interconnect structure 170 is disposed on the back side of the substrate 102, and thus the interconnect structure 170 can also be referred to as a back side interconnect structure. In some embodiments, the interconnect structure 170 may include at least one dielectric layer 175. The interconnect structure 170 further includes metal pad 176A, 176B, and 176C disposed in the dielectric layer 175. In greater detail, the metal pads 176A, 176B, and 176C are electrically connected to the conductive structures 140A, 140B, and 140G through the respective conductive vias 160. In some embodiments, the metal pad 176A serves as an input terminal Vᵢₙ of the semiconductor die 100A, the metal pad 176B serves as a ground terminal Vₛₛ of the semiconductor die 100A, and the metal pad 176C serves as an output terminal Vₒᵤₜ of the semiconductor die 100A. In some embodiments, the bottom surfaces of the metal pads 176A, 176B, and 176C may be substantially level with bottom surface of the dielectric layer 175.

Accordingly, the semiconductor die 100A may include a top input terminal (e.g., the metal pad 146A) and a bottom input terminal (e.g., the metal pad 176A) on the front side and the back side of the semiconductor die 100A, respectively. Similarly, the semiconductor die 100A may include a top ground terminal (e.g., the metal pad 146B) and a bottom ground terminal (e.g., the metal pad 176B) on the front side and the back side of the semiconductor die 100A, respectively. Moreover, the semiconductor die 100A may include a top output terminal (e.g., the metal pad 146C) and a bottom output terminal (e.g., the metal pad 176C) on the front side and the back side of the semiconductor die 100A, respectively.

With respect to the routing structure 300A of the package structure 10A, the routing structure 300A is disposed over the front side of the semiconductor die 100A, and is configured to re-route a path of circuitry from the semiconductor die 100A and redistribute the I/O terminals and the ground terminal of the semiconductor die 100A. In some embodiments, the routing structure 300A can also be referred to as a redistribution structure.

In some embodiments, the routing structure 300A may include several dielectric layers 310 stacking one above another. According to some embodiments, the dielectric layers 310 are made of one or more suitable dielectric materials such as an oxide (e.g., silicon oxide), a nitride (e.g., silicon nitride), a polymer material, a polyimide material, a low-k dielectric material, another dielectric material, the like, or a combination thereof. In some embodiments, some or all of the dielectric layers 310 may comprise the same insulating materials and/or some of the dielectric layers 310 may comprise different insulating materials from the other layers. In some embodiments, the dielectric layers 310 can be collectively referred to as a dielectric structure 312. In some embodiments, the dielectric layers 310 of the routing structure 300A are made of a different material than the dielectric layers 135 of the interconnect structure 130.

The routing structure 300A further includes several conductive structures 320A, 320B, and 320C disposed in the dielectric structure 312 formed by the dielectric layers 310. In some embodiments, each of the conductive structures 320A, 320B, and 320C may include several metal lines 322 and metal vias 324 coupled with the respective metal lines 322. In some embodiments, each of the metal lines 322 is laterally extended within the respective dielectric layer 310, while each of the metal vias 324 is vertically extended within the respective dielectric layer 310. In some embodiments, the metal lines 322 and metal vias 324 are stacked alternately within the dielectric structure 312 formed by dielectric layers 310. Each of the conductive structures 320A, 320B, and 320C further include a metal pad 326 electrically connected to the respective metal lines 322, and an external connector 328 disposed on the metal pad 326. In some embodiments, the metal pad 326 can also be referred to as under-ball metallurgy (UBM) layer. In some embodiments, the external connector 328 may be a solder joint, a solder bump, a solder ball, a ball grid array (BGA) ball, a controlled collapse chip connection (C4) bump, microbump, a conductive pillar, post or the like. In some embodiments, the external connector 328 includes metals such as lead, tin, copper, gold, nickel, or the like.

In some embodiments, the routing structure 300A may include substantially a same width as the interconnect structure 130. That is, sidewalls of the routing structure 300A may be aligned with sidewalls of the interconnect structure 130. However, in other embodiments, the routing structure 300A may be wider than or narrower than the interconnect structure 130. That is, sidewalls of the routing structure 300A may be offset from sidewalls of the interconnect structure 130.

With respect to the semiconductor die 400, in some embodiments, the semiconductor die 400 is a logic device die, graphics processing unit (GPU) die, application processing (AP) die, memory die, high bandwidth memory (HBM) die or the like. In some embodiments, the semiconductor die 400 is a chip or a stack of chips. In some embodiments, the semiconductor die 400 has a top profile in a quadrilateral, a rectangular or a square shape. In some embodiments, the semiconductor die 400 may include metal pads 410A, 410B, and 410C disposed on a surface of the semiconductor die 400. The metal pads 410A, 410B, and 410C are in contact with the external connectors 328 of the conductive structures 320A, 320B, and 320C in the routing structure 300A, respectively. As a result, the input terminal of the semiconductor die 100A is electrically connected to the metal pad 410A of the semiconductor die 400, the ground terminal of the semiconductor die 100A is electrically connected to the metal pad 410B of the semiconductor die 400, and the output terminal is electrically connected to the metal pad 410C of the semiconductor die 400. Accordingly, the metal pads 410A, 410B, and 410C can also be referred to as input terminal Vᵢₙ, ground terminal Vₛₛ, and output terminal Vₒᵤₜ of the semiconductor die 400, respectively. In some embodiments, because the semiconductor die 400 is at the highest position of the package structure 10A, and the semiconductor die 400 can also be referred to as a top die.

With respect to the routing structure 300B of the package structure 10A, the routing structure 300B is disposed over the back side of the semiconductor die 100A, and is configured to re-route a path of circuitry from the semiconductor die 100A and redistribute the I/O terminals and the ground terminal of the semiconductor die 100A. It is noted that the routing structure 300B may include similar configuration as the routing structure 300A, and thus similar elements are labeled the same, and relevant details will not be repeated for brevity. In some embodiments, the routing structure 300B can also be referred to as a redistribution structure.

In some embodiments, the routing structure 300B may include a dielectric structure 312 including several dielectric layers 310 stacking one above another. The routing structure 300B further includes several conductive structures 330A, 330B, and 330C disposed in the dielectric structure 312 formed by the dielectric layers 310. In some embodiments, each of the conductive structures 330A, 330B, and 330C includes metal lines 322, metal vias 324, a metal pad 326, and and an external connector 328. In some embodiments, the dielectric layers 310 of the routing structure 300B are made of a different material than the dielectric layers 175 of the interconnect structure 170.

With respect to the package substrate 500, in some embodiments, the package substrate 500 is a printed circuit board (PCB). In some embodiments, the package substrate 500 includes several conductive traces and several electrical components such as transistor, diode, etc. disposed within the package substrate 500. In some embodiments, the package substrate 500 may include metal pads 510A, 510B, and 510C disposed on top surface of the package substrate 500. The metal pads 510A, 510B, and 510C are in contact with the external connectors 328 of the conductive structures 330A, 330B, and 330C in the routing structure 300B, respectively. As a result, the input terminal of the semiconductor die 100A is electrically connected to the metal pad 510A of the package substrate 500, the ground terminal of the semiconductor die 100A is electrically connected to the metal pad 510B of the package substrate 500, and the output terminal is electrically connected to the metal pad 510C of the package substrate 500. Accordingly, the metal pads 510A, 510B, and 510C can also be referred to as input terminal Vᵢₙ, ground terminal Vₛₛ, and output terminal Vₒᵤₜ of the package substrate 500, respectively. The package substrate 500 further includes external connectors 520 disposed on bottom surface of the package substrate 500. In some embodiments, the external connector 520 may be a solder joint, a solder bump, a solder ball, a ball grid array (BGA) ball, a controlled collapse chip connection (C4) bump, microbump, a conductive pillar, post or the like. In some embodiments, the external connector 520 includes metals such as lead, tin, copper, gold, nickel, or the like.

The package structure 10A further includes an underfill 600 between the routing structure 300A and the semiconductor die 400, and an underfill 610 between the routing structure 300B and the package substrate 500. In some embodiments, The underfills 600 and 610 may include a molding compound, an epoxy, an underfill, a molding underfill (MUF), a resin, or the like. The underfills 600 and 610 can protect the external connectors 328 and provide structural support.

FIG. 1C is a circuit diagram of a semiconductor die in accordance with some embodiments. In greater detail, FIG. 1C is a circuit diagram of the semiconductor die 100A of FIG. 1A. In some embodiments, when the semiconductor die 100A is a coupled inductor voltage regulator (CLVR), the circuit diagram of the semiconductor die 100A includes the transistor TR1, the transistor TR2, and the inductor 150 as discussed in FIG. 1A. In some embodiments, the drain region of the transistor TR1 and the drain region of the transistor TR2 are electrically coupled with each other, and are electrically coupled to the first side of the inductor 150. Moreover, the input terminal Vᵢₙ is electrically connected to the source region of the transistor TR2, the ground terminal Vₛₛ is electrically connected to the source region of the transistor TR1, and the output terminal Vₒᵤₜ is electrically connected to the second side of the inductor 150.

FIG. 1D is a top view of a semiconductor die in accordance with some embodiments. In greater detail, FIG. 1D is a top view of the semiconductor die 100A of FIG. 1A. In some embodiments, when the semiconductor die 100A is a coupled inductor voltage regulator (CLVR), the semiconductor die 100A may include several CLVR cells 100A_C, in which the CLVR cells 100A_C may include substantially the same configuration. The CLVR cells 100A_C may be arranged in a matrix. For example, the CLVR cells 100A_C in FIG. 1D are arranged in a 4×4 matrix. However, the disclosure is not limited thereto, the arrangement and the number of the CLVR cells 100A_C may be different in other embodiments.

In some embodiments, each CLVR cell 100A_C may include two inductors 150, in which each inductor 150 may include a pair of conductors 152. The CLVR cell 100A_C may include a plurality of input terminals Vᵢₙ, a plurality of output terminal Vₒᵤₜ, and a plurality of output terminal Vₒᵤₜ. In some embodiments, the input terminals Vᵢₙ of all CLVR cells 100A_C may be electrically connected with each other, and the output terminals Vₒᵤₜ of all CLVR cells 100A_C may be electrically connected with each other, and the output terminals Vₒᵤₜ of all CLVR cells 100A_C may be electrically connected with each other. Accordingly, the equivalent circuit of FIG. 1D can be shown in FIG. 1C.

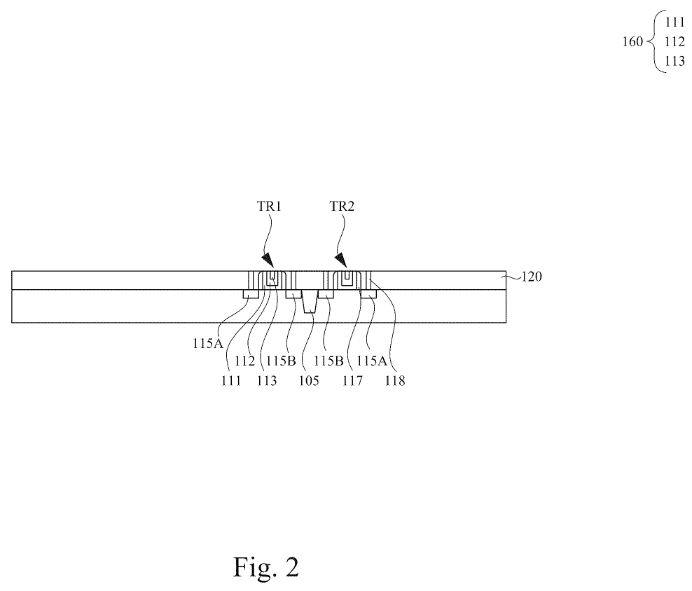

FIGS. 2 to 7 illustrate a method in various stages of forming a package structure in accordance with some embodiments of the present disclosure. Specifically, FIGS. 2 to 7 illustrate a method for forming the package structure 10A as shown in FIG. 1A. Accordingly, similar elements will be labeled the same, and relevant details will not be repeated for brevity. Although FIGS. 2 to 7 are described as a series of acts, it will be appreciated that these acts are not limiting in that the order of the acts can be altered in other embodiments, and the methods disclosed are also applicable to other structures. In other embodiments, some acts that are illustrated and/or described may be omitted in whole or in part.

Reference is made to FIG. 2. Shown there is a substrate 102. A shallow trench isolation (STI) structure 105 is formed in the substrate 102. The STI structure 105 can be formed by, for example, etching the substrate 102 to form a recess, filling the recess with a dielectric material, and then performing a planarization process (e.g., CMP) to remove excess dielectric material until the substrate 102 is exposed.

Then, transistors TR1 and TR2 are formed over the substrate 102. In some embodiments, the transistors TR1 and TR2 can be formed by, for example, forming gate structures 110 over the substrate 102, forming gate spacers 117 on sidewalls of the gate structure 110, and forming source/drain features 115A and 115B over the substrate 102 and on opposite sides of the gate structures 110.

In some embodiments where the gate structures 110 are formed through a gate-last process, a replacement gate (RPG) process may be applied. For example, dummy gate structures, such as polysilicon, are formed over the substrate 102, and gate spacers 117 are formed on sidewalls of dummy gate structures. After the gate spacers 117 are formed, source/drain features 115A and 115B are formed over the substrate 102. Then, an interlayer dielectric (ILD) layer 120 is formed over the substrate 102, covering the source/drain features 115A and 115B, and laterally surrounding the dummy gate structures. The dummy gate structures are then removed to form gate trenches between the gate spacers 117. A gate dielectric layer 111, a work function metal layer 112, and a filling metal 113 are deposited in the gate trenches, and a planarization process (e.g., CMP) is performed to remove excess materials of the gate dielectric layer 111, the work function metal layer 112, and the filling metal 113 until the ILD layer 120 is exposed.

Source/drain contacts 118 are formed in the ILD layer 120 and electrically connected to the source/drain features 115A and 115B, respectively. The source/drain contacts 118 can be formed by, for example, etching the ILD layer 120 to form openings in the ILD layer 120, filling the openings with conductive materials, and then performing a planarization process (e.g., CMP) to remove excess dielectric materials until the ILD layer 120 is exposed.

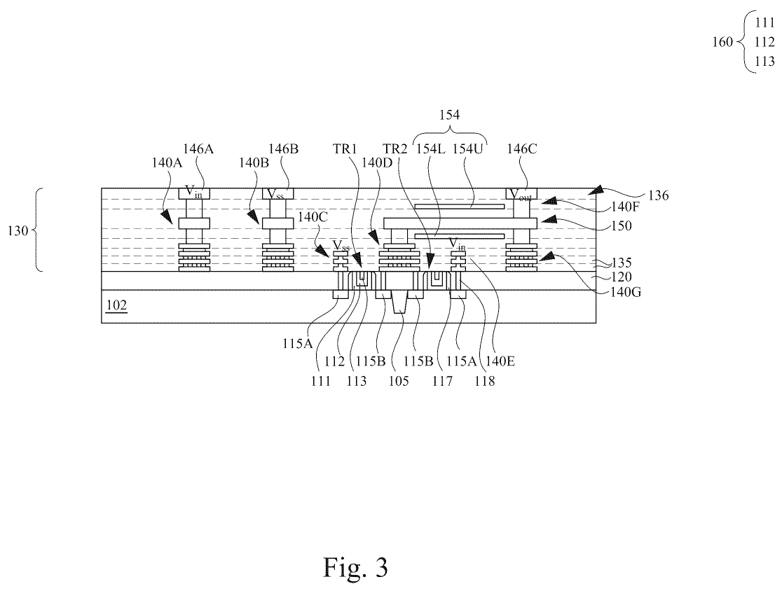

Reference is made to FIG. 3. An interconnect structure 130 is formed over the ILD layer 120. The formation of the interconnect structure 130 may include the following steps. A dielectric layer 135 may be formed on the ILD layer 120. Then, the dielectric layer 135 is patterned to form openings. Conductive material is formed in the openings and over top surface of the dielectric layer 135, and the conductive materials are patterned to form the metal lines 142 and metal vias 144. Afterwards, another dielectric layer 135 is formed over the previously formed dielectric layer 135. Then, the step of patterning the dielectric layer 135, forming and patterning the conductive material may be repeated several times to obtain the interconnect structure 130. In some embodiments, at least one inductor 150 is formed in the interconnect structure 130 during the formation of the interconnect structure 130, and will be discussed in more detail later.

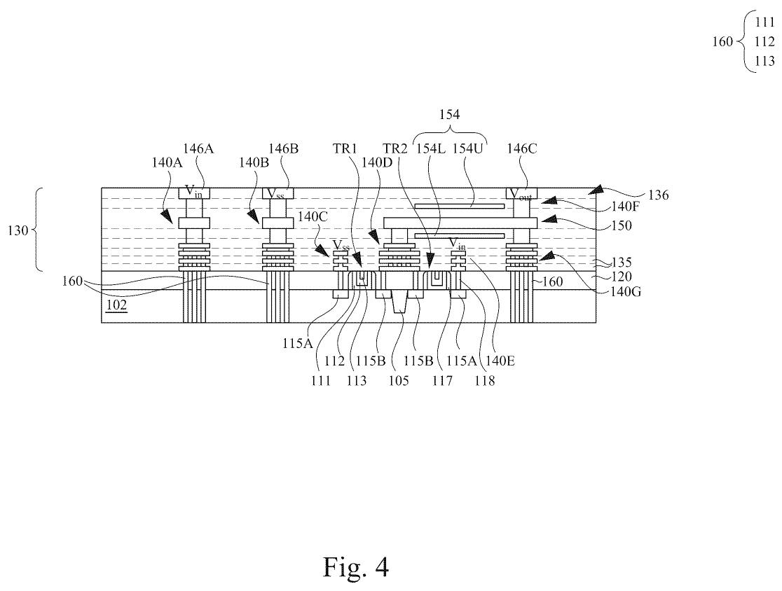

Reference is made to FIG. 4. Conductive vias 160 are formed extending through the substrate 100 and electrically connected to the interconnect structure 130. The conductive vias 160 may be formed by, for example, performing an etching process from the backside of the substrate 102 to form openings extending through the substrate 100 and/or the ILD layer 120 and exposing the interconnect structure 130, filling the openings with conductive material, and then performing a planarization process (e.g., CMP) to remove excess conductive material until the substrate 100 is exposed.

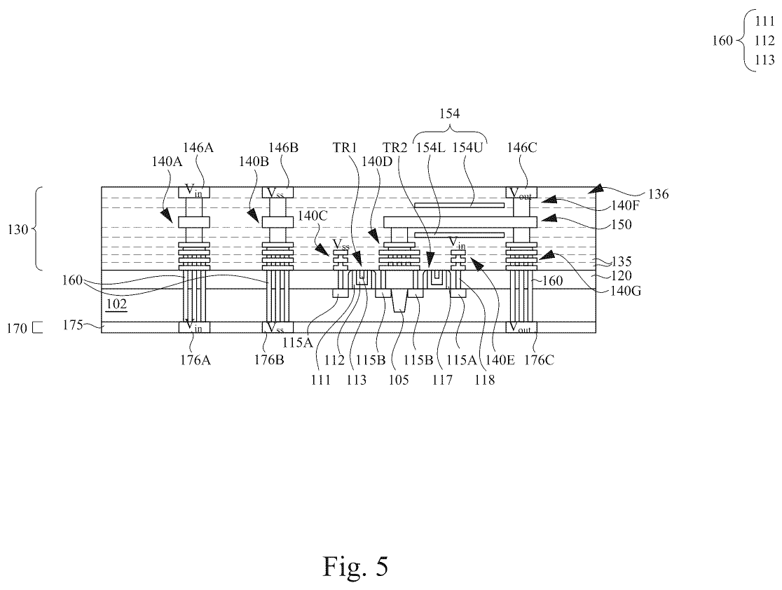

Reference is made to FIG. 5. An interconnect structure 170 is formed on the back side of the substrate 100 and electrically connected to the conductive vias 160. The formation of the interconnect structure 170 may be similar to those described with respect to the interconnect structure 130, and thus relevant details will not be repeated. Accordingly, the semiconductor die 100A is formed.

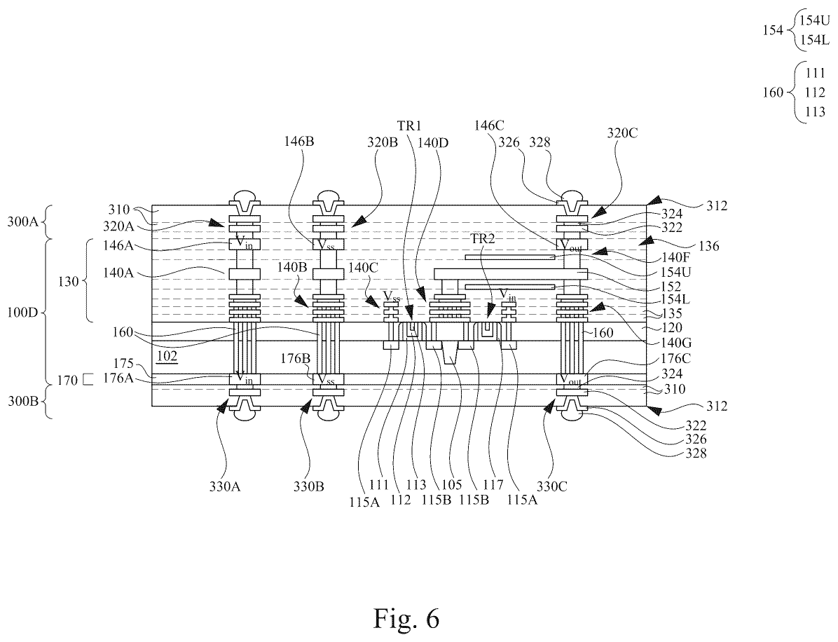

Reference is made to FIG. 6. A routing structure 300A is formed on a first side of the semiconductor die 100A, and a routing structure 300B is formed on a second side of the semiconductor die 100A. The routing structures 300A and 300B can be formed by following steps. A dielectric layer 310 is formed over the semiconductor die 100A, and a seed material layer (not shown) is blanketly formed over the dielectric layer 310. Then, a mask pattern (not shown) having openings is formed on the seed material layer. Afterwards, a plating process is performed to form a conductive material on the seed material layer exposed by the openings of the mask pattern. The mask pattern and the underlying seed material layer are then removed by a stripping process and an etching process. The remaining seed material layer and the remaining conductive material layer then constitute the metal lines 322 and/or the metal vias 324. Then, the step of forming the dielectric layer 135 and forming the seed material layer and the conductive material layer may be repeated several times to obtain the routing structures 300A and 300B having multiple layers. In some embodiments, metal pads 326 and external connectors 328 are formed on the outmost dielectric layer 135 of the routing structures 300A and 300B. For example, the outmost dielectric layer 135 is patterned to form openings, and the metal pads 326 are formed lining the openings of the outmost dielectric layer 135. Then, the external connectors 328 may be attached to the metal pads 326 through a solder flux, or other suitable methods.

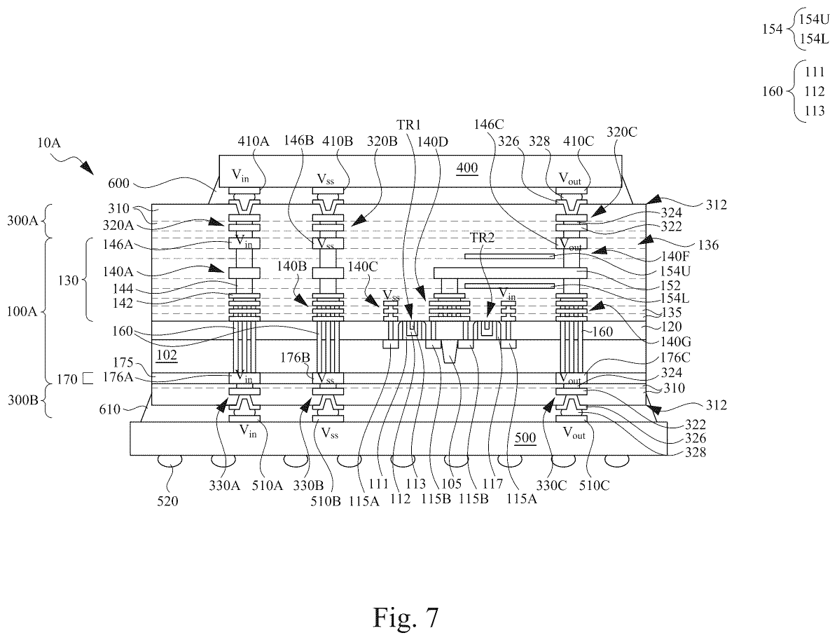

Reference is made to FIG. 7. A semiconductor die 400 is bonded to the routing structure 300A and a package substrate 500 is bonded to the routing structure 300B. In some embodiments, the semiconductor die 400 and the package substrate 500 are bonded respectively to the routing structures 300A and 300B through flip-chip bonding. For example, the external connectors 328 of the routing structure 300A are respectively connected to the respective metal pads 410A, 410B, and 410C of the semiconductor die 400, and the external connectors 328 of the routing structure 300B are respectively connected to the respective metal pads 510A, 510B, and 510C of the package substrate 500. Thereafter, a reflow process is performed to ensure the adhesion between the semiconductor die 400 and the routing structure 300A, and the adhesion between the semiconductor die 400 and the package substrate 500. It is noted that the semiconductor die 400 may first be bonded to the routing structure 300A, and the package substrate 500 is then bonded to the routing structure 300B. In some embodiments, an underfill 600 is formed between the routing structure 300A and the semiconductor die 400, and an underfill 610 is formed between the routing structure 300B and the package substrate 500.

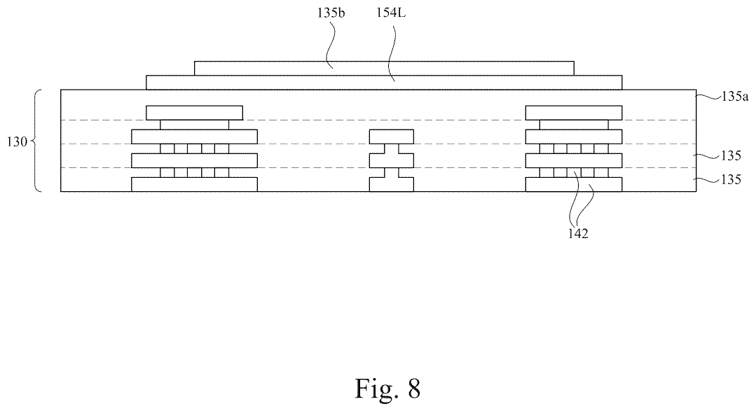

FIGS. 8 to 12 illustrate a method in various stages of forming an inductor in accordance with some embodiments of the present disclosure. Specifically, FIGS. 8 to 12 illustrate a method for forming the inductor 150 as shown in FIG. 1B. Accordingly, similar elements will be labeled the same, and relevant details will not be repeated for brevity. Although FIGS. 8 to 12 are described as a series of acts, it will be appreciated that these acts are not limiting in that the order of the acts can be altered in other embodiments, and the methods disclosed are also applicable to other structures. In other embodiments, some acts that are illustrated and/or described may be omitted in whole or in part.

Reference is made to FIG. 8. During the formation of the interconnect structure 130, a plurality of dielectric layers 135, metal lines 142, and metal vias 144 may be formed. A lower magnetic layer 154L is formed over a dielectric layer 135a. A dielectric layer 135b is formed over the lower magnetic layer 154L. In some embodiments, the dielectric layer 135b is patterned, such that top surfaces of opposite ends of the lower magnetic layer 154L are exposed and free of coverage by the dielectric layer 135b. The lower magnetic layer 154L may be deposited using a chemical vapor deposition process, a physical vapor deposition process, a plating process, or using another processing technique.

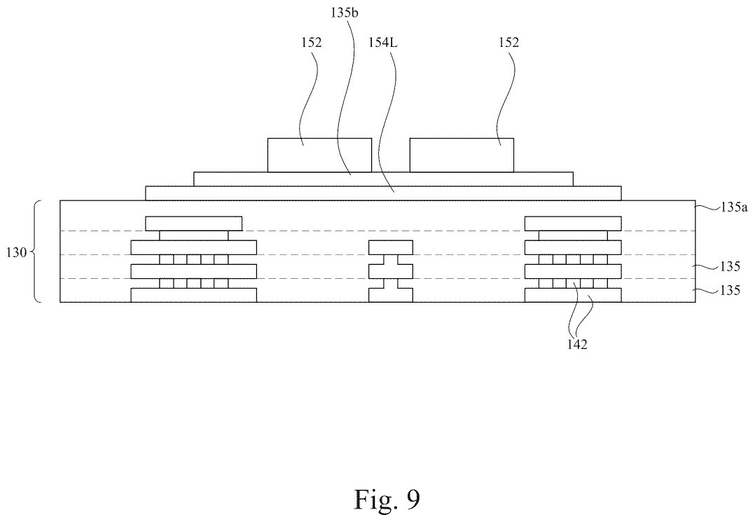

Reference is made to FIG. 9. Conductors 152 are formed over the dielectric layer 135b. The conductors 152 can be formed by depositing a conductive material over the dielectric layer 135b, and then patterning the conductive material. The conductors 152 may be deposited using a chemical vapor deposition process, a physical vapor deposition process, a plating process, or using another processing technique.

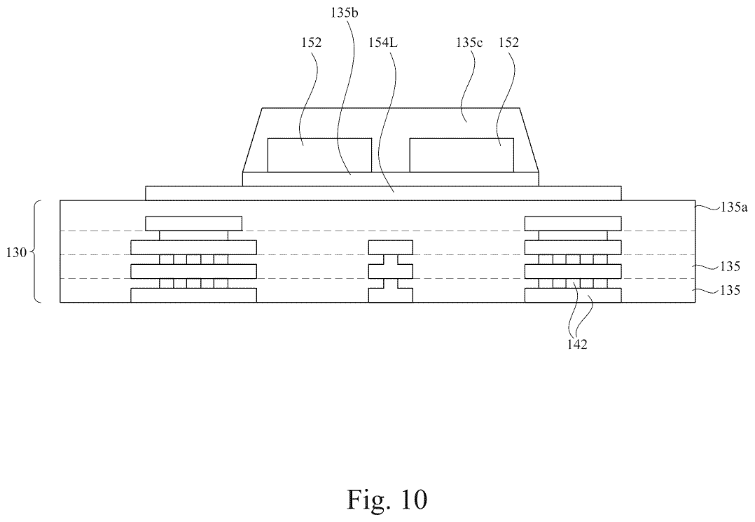

Reference is made to FIG. 10. A dielectric layer 135c is formed over the dielectric layer 135b and covering the conductors 152. In greater detail, the dielectric layer 135b is patterned to expose the top surface of opposite ends of the lower magnetic layer 154L, and the remaining dielectric layer 135c covers top surface and opposite sidewalls of the conductors 152.

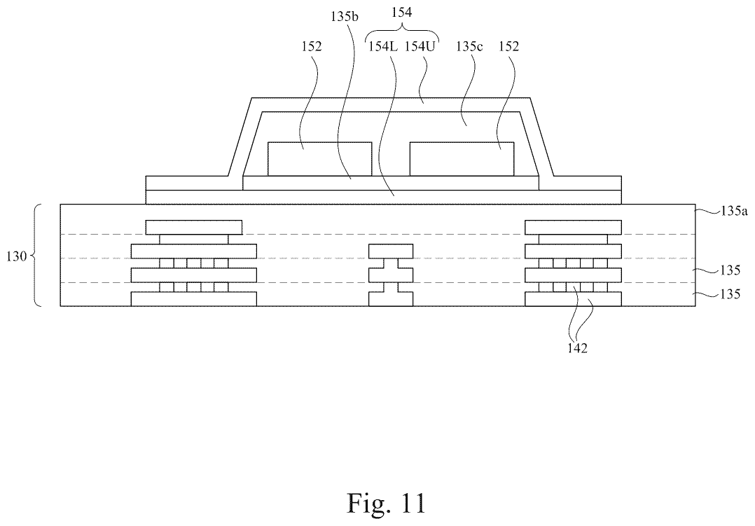

Reference is made to FIG. 11. An upper magnetic layer 154U is formed over the dielectric layer 135c and in contact with the lower magnetic layer 154L. In greater detail, opposite ends of the upper magnetic layer 154U may be in contact with opposite ends of the lower magnetic layer 154L to form a ring-shape structure that surrounds the conductors 152 as shown in FIG. 11. The upper magnetic layer 154U can be formed by, for example, depositing a magnetic layer and then patterning the magnetic layer. Accordingly, the inductor 150 is formed.

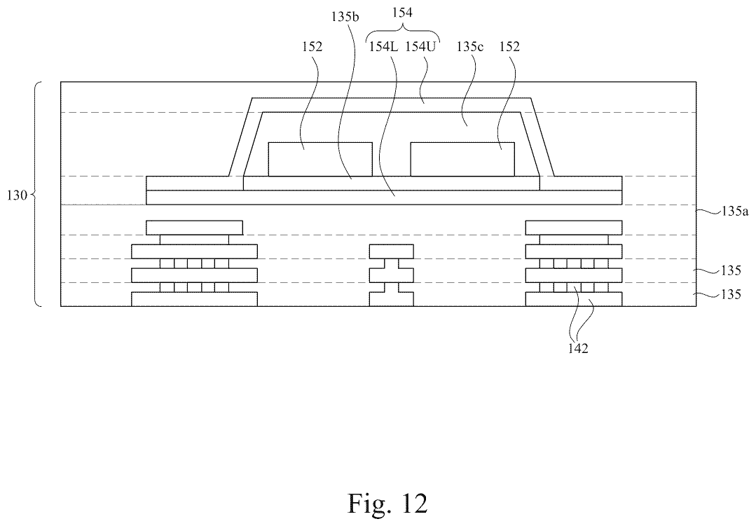

Reference is made to FIG. 12. Once the inductor 150 is formed, other dielectric layers 135, metal lines 142, and metal vias 144 may be formed over the inductor 150. In the depicted embodiments, the inductor 150 is formed in the middle portion of the interconnect structure 130. For example, the top surface of the upper magnetic layer 154U of the inductor 150 is lower than the top surface of the topmost dielectric layer 135, and the bottom surface of the lower magnetic layer 154L is higher than the bottom surface of the bottommost dielectric layer 135.

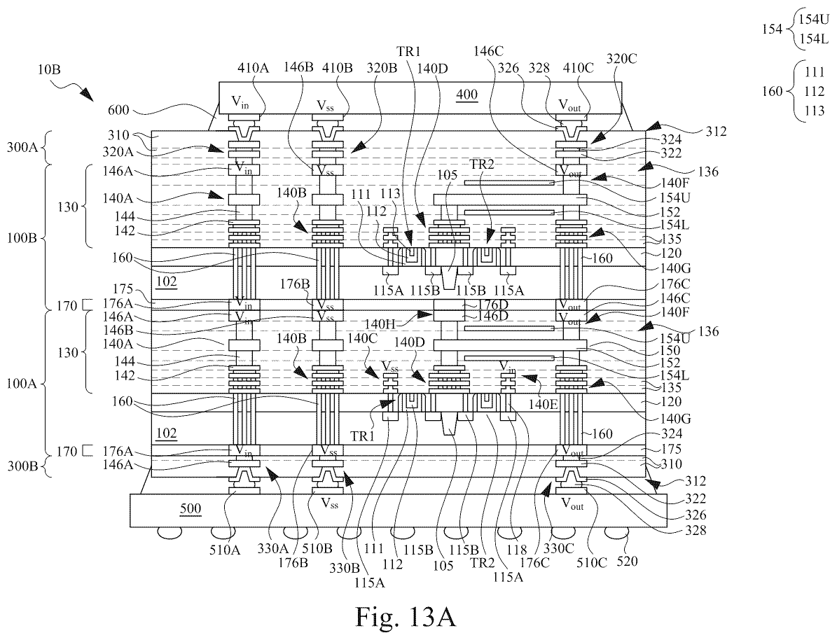

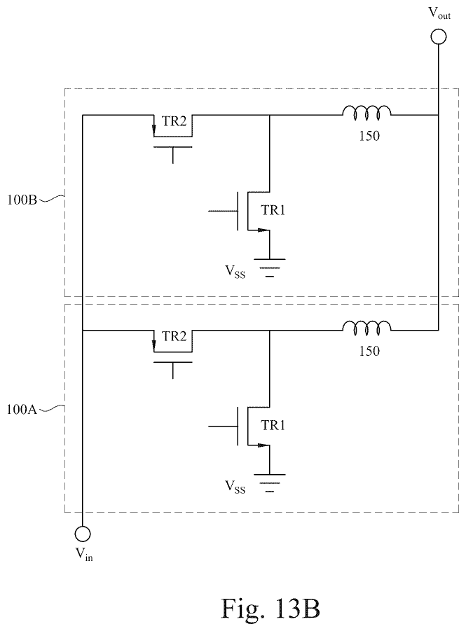

FIG. 13A is a cross-sectional view of a package structure in accordance with some embodiments. Shown there is a package structure 10B. It is noted that some elements in the package structure 10B of FIG. 13A are similar to those described with respect to the package structure 10A in FIG. 1A, such elements are labeled the same, and relevant details will not be repeated for brevity.

FIG. 13A is different from FIG. 1A in that the package structure 10B of FIG. 13A further includes a semiconductor die 100B stacking over the semiconductor die 100A, in which the semiconductor die 100B may include substantially the same configuration as the semiconductor die 100A. In some embodiments, the interconnect structure 170 of the semiconductor die 100B is bonded to the interconnect structure 130 of the semiconductor die 100A through hybrid bonding. In the hybrid bonding, the metal pads 176A, 176B, and 176C of the interconnect structure 170 of the semiconductor die 100B are bonded to the metal pads 146A, 146B, and 146C of the interconnect structure 130 of the semiconductor die 100A through metal-to-metal direct bonding. In some embodiments, the metal-to-metal direct bonding may be copper-to-copper direct bonding. On the other hand, surface dielectric layer 175 of the interconnect structure 170 of the semiconductor die 100B is bonded to surface dielectric layer 135 of the interconnect structure 130 of the semiconductor die 100A through dielectric-to-dielectric bonding, which may be fusion bonding.

The package structure 10B includes a routing structure 300A electrically connected to the semiconductor die 100B, and a routing structure 300B electrically connected to the semiconductor die 100A. The connection between the routing structure 300A and the semiconductor die 100B may be similar to the connection between the routing structure 300A and the semiconductor die 100A as discussed in FIG. 1A, and thus relevant details are not repeated for brevity.

FIG. 13B is a circuit diagram of a semiconductor die in accordance with some embodiments. In greater detail, FIG. 13B is a circuit diagram of the semiconductor dies 100A and 100B of FIG. 13A. In some embodiments, when the semiconductor dies 100A and 100B are coupled inductor voltage regulators (CLVRs), the circuit diagram of each the semiconductor dies 100A and 100B includes the transistor TR1, the transistor TR2, and the inductor 150 as shown in FIG. 13A. In each of the semiconductor dies 100A and 100B, the drain region of the transistor TR1 and the drain region of the transistor TR2 are electrically coupled with each other, and are electrically coupled to a first side of the inductor 150. Moreover, the input terminal Vᵢₙ is electrically connected to the source regions of the transistors TR2 of the semiconductor dies 100A and 100B, the ground terminal Vₛₛ is electrically connected to the source regions of the transistors TR1 of the semiconductor dies 100A and 100B, and the output terminal Vₒᵤₜ is electrically connected to second sides of the inductors 150 of the semiconductor dies 100A and 100B.

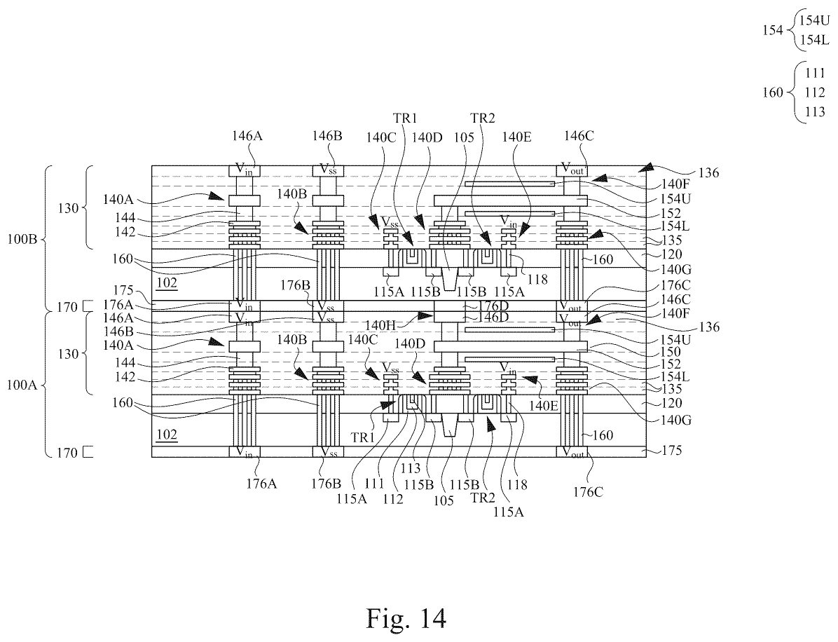

FIGS. 14 to 16 illustrate a method in various stages of forming a package structure in accordance with some embodiments of the present disclosure. Specifically, FIGS. 14 to 16 illustrate a method for forming the package structure 10B as shown in FIG. 13A. Accordingly, similar elements will be labeled the same, and relevant details will not be repeated for brevity. Moreover, some processes for forming the package structure 10B may be similar to those descried with respect to the formation of the package structure 10A as discussed in FIGS. 2 to 7, and relevant details will not be repeated for brevity.

Reference is made to FIG. 14. A semiconductor die 100A and 100B are provided. In some embodiments, each of the semiconductor die 100A and 100B can be formed through the method as discussed in FIGS. 2 to 5. The semiconductor dies 100A and 100B are bonded with each other through hybrid bonding. To achieve the hybrid bonding, a pre-bonding is performed by lightly pressing semiconductor die 100A against the semiconductor die 100B, in which the metal pads 176A, 176B, and 176C of the interconnect structure 170 of the semiconductor die 100B are in contact with the metal pads 146A, 146B, and 146C of the interconnect structure 130 of the semiconductor die 100A, and surface dielectric layer 175 of the interconnect structure 170 of the semiconductor die 100B is in contact with surface dielectric layer 135 of the interconnect structure 130 of the semiconductor die 100A. After the semiconductor dies 100A and 100B are pre-bonded, an annealing process is performed to cause the inter-diffusion of the metals in the metal pads 176A, 176B, and 176C and the corresponding metal pads 146A, 146B, and 146C. Through the hybrid bonding, the metal pads 176A, 176B, and 176C are bonded to the corresponding metal pads 146A, 146B, and 146C through direct metal bonding caused by metal inter-diffusion.

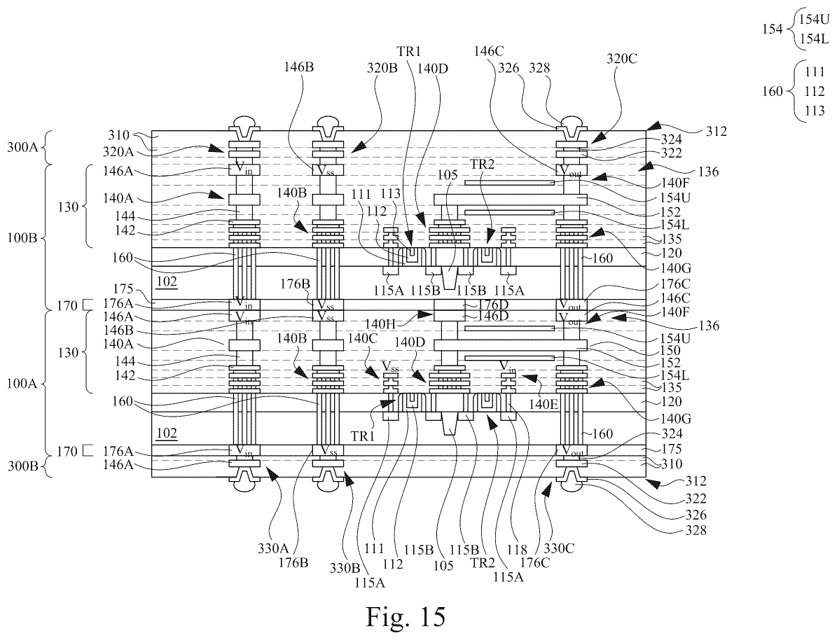

Reference is made to FIG. 15, a routing structure 300A is formed on of the semiconductor die 100B, and a routing structure 300B is formed on the semiconductor die 100B, respectively.

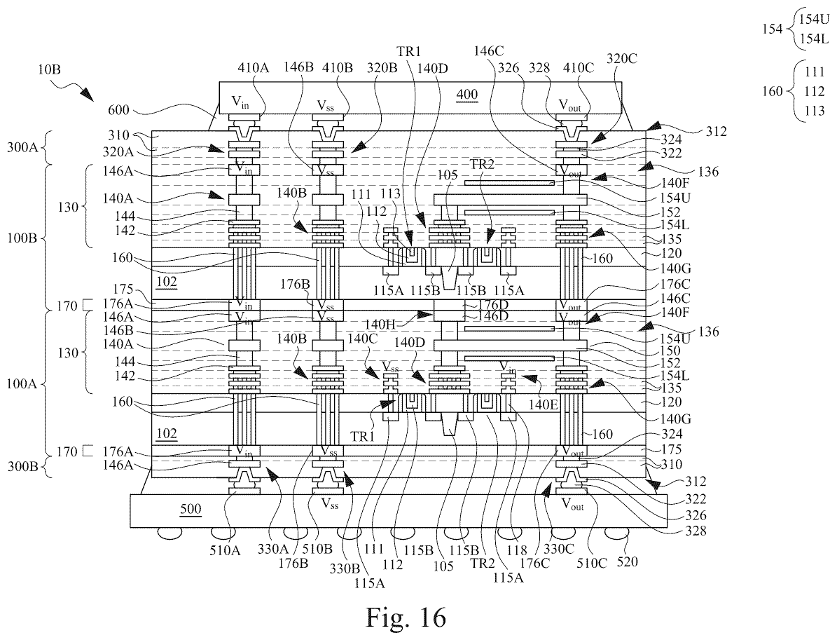

Reference is made to FIG. 16. A semiconductor die 400 is bonded to the routing structure 300A and a package substrate 500 is bonded to the routing structure 300B. Afterwards, an underfill 600 is formed between the routing structure 300A and the semiconductor die 400, and an underfill 610 is formed between the routing structure 300B and the package substrate 500.

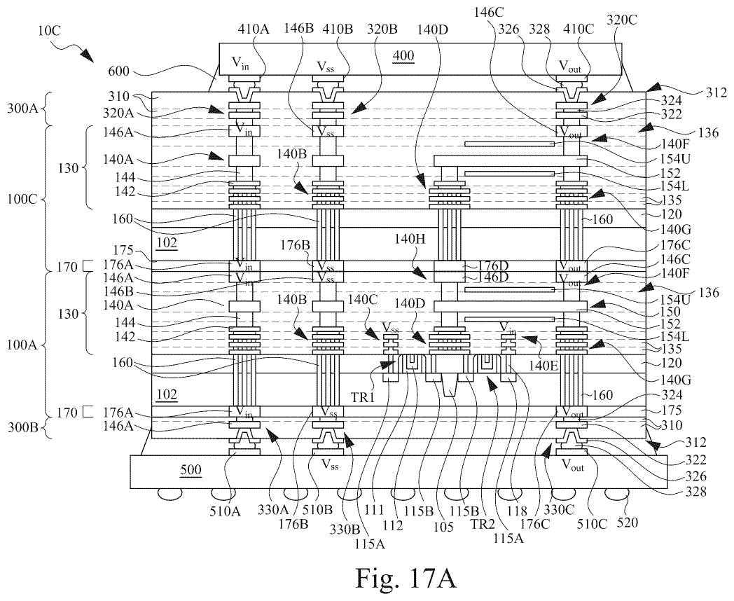

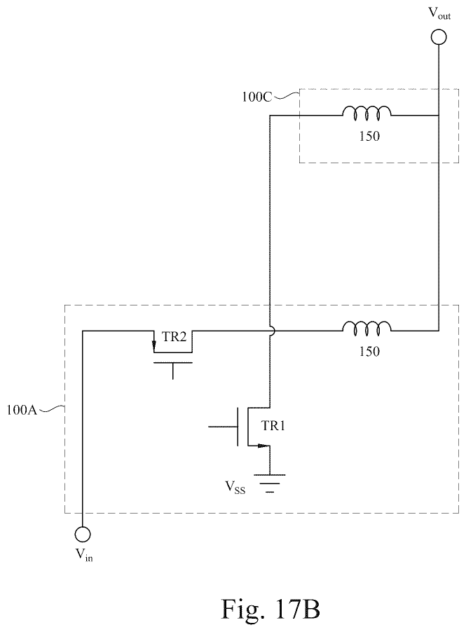

FIG. 17A is a cross-sectional view of a package structure in accordance with some embodiments. Shown there is a package structure 10C. It is noted that some elements in the package structure 10C of FIG. 17A are similar to those described with respect to the package structures 10A and 10B described above, such elements are labeled the same, and relevant details will not be repeated for brevity.

The package structure 10C of FIG. 17A includes a semiconductor die 100C stacking over the semiconductor die 100A, in which the semiconductor die 100C may include a different configuration than the semiconductor die 100A. In some embodiments, the semiconductor die 100C may be free of active devices, such as the transistors TR1 and TR2 in the semiconductor die 100A.

With respect to the semiconductor die 100A, the interconnect structure 130 of the semiconductor die 100A further includes a conductive structure 140H in contact with top surface of the first side of the inductor 150, and the conductive structure 140H includes a metal pad 146D exposed through the dielectric structure 136 of the interconnect structure 130.

With respect to the semiconductor die 100C, the interconnect structure 170 of the semiconductor die 100B further includes a metal pad 176D in the dielectric layer 175 of the interconnect structure 170, in which the metal pad 176D of the semiconductor die 100B is connected to the metal pad 146D of the semiconductor die 100A through hybrid bonding. Moreover, the semiconductor die 100C further includes conductive vias 160 connecting the metal pad 176D of the interconnect structure 170 to the conductive structure 140D of the interconnect structure 130. As a result, the first side of the inductor 150 in the semiconductor die 100A is electrically connected to the first side of the inductor 150 in the semiconductor die 100C.

FIG. 17B is a circuit diagram of a semiconductor die in accordance with some embodiments. In greater detail, FIG. 17B is a circuit diagram of the semiconductor dies 100A and 100C of FIG. 17A. In some embodiments, when the semiconductor die 100A is a coupled inductor voltage regulators (CLVR), the circuit diagram of the semiconductor die 100A includes the transistor TR1, the transistor TR2, and the inductor 150. On the other hand, the semiconductor die 100C includes an inductor 150. In some embodiments, the first end of the inductor 150 in the semiconductor die 100C is electrically connected to the first end of the inductor 150 in the semiconductor die 100A, and the second end of the inductor 150 in the semiconductor die 100C is electrically connected to the second end of the inductor 150 in the semiconductor die 100A.

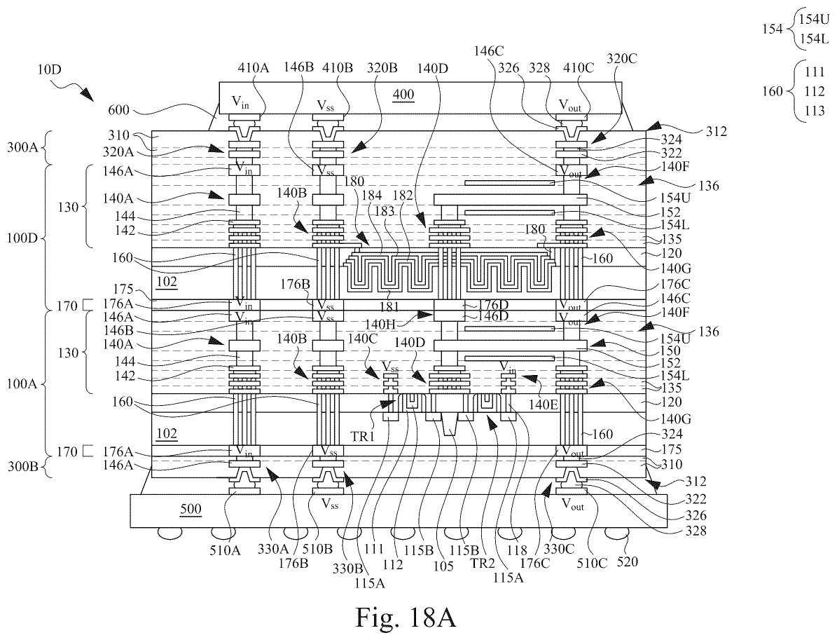

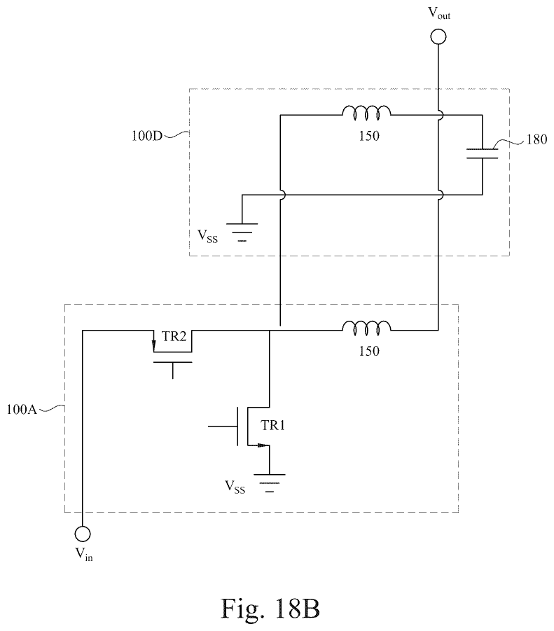

FIG. 18A is a cross-sectional view of a package structure in accordance with some embodiments. Shown there is a package structure 10D. It is noted that some elements in the package structure 10D of FIG. 18A are similar to those described with respect to the package structure 10C in FIG. 17A, such elements are labeled the same, and relevant details will not be repeated for brevity.

The package structure 10D of FIG. 18A includes a semiconductor die 100D stacking over the semiconductor die 100A, in which the semiconductor die 100D is similar to the semiconductor die 100C of FIG. 17A. In some embodiments, the semiconductor die 100D may be free of active devices, such as the transistors TR1 and TR2 in the semiconductor die 100A. The package structure 10D of FIG. 18A is different from the package structure 10C of FIG. 17A, in that the semiconductor die 100D further comprises a capacitor 180. In some embodiments, capacitor 180 is a deep trench capacitor (DTC) structure. In some embodiments, the inductor 150 may vertically overlap a portion of the capacitor 180.

With respect to the capacitor 180, the capacitor 180 is formed in several separate trenches in the substrate 102. That is, the capacitor 180 may include several portions extending into the substrate 102. The capacitor 180 may include a dielectric liner 181 lining a surface of the substrate 102, a capacitor electrode 182 over the dielectric liner 181, a capacitor dielectric layer 183 over the capacitor electrode 182, and a capacitor electrode 184 over the capacitor dielectric layer 183. It is noted that in the embodiments of FIG. 18A, the capacitor 180 include a single capacitor dielectric layer sandwiched between a pair of capacitor electrodes. However, the capacitor 180 may include a plurality of capacitor dielectric layers and capacitor electrodes stacking alternately.

In some embodiments, the dielectric liner 181 may comprise a dielectric material, such as silicon oxide, silicon oxynitride (SiON), silicon carboxynitride (SiCON). In some embodiments, each of the capacitor electrodes 182 and 184 may comprise a conductive material such as doped silicon, polysilicon, copper, tungsten, an aluminum or copper alloy, titanium, titanium nitride, tantalum, tantalum nitride, a combination thereof, or the like. In some embodiments, the capacitor dielectric layer 183 may comprise a high-K dielectric material such as aluminum oxide, zirconium oxide, a combination thereof, a multilayer thereof, or the like.

The semiconductor die 100D further includes a contact 118 electrically connecting the capacitor electrode 184 of the capacitor 180 to the conductive structure 140B of the interconnect structure 130 of the semiconductor die 100D. The semiconductor die 100D further includes another contact 118 electrically connecting the capacitor electrode 182 of the capacitor 180 to the conductive structure 140G of the interconnect structure 130 of the semiconductor die 100D. Accordingly, it can be seen that a first end of the capacitor 180 is electrically connected to the ground terminal Vₛₛ, and a second end of the capacitor 180 is electrically connected to the output terminal Vₒᵤₜ and the second end of the inductor 150.

It should be noted that, in FIG. 18A, some of the conductive vias 160 in the substrate 102 are illustrated as passing through the capacitor 180, while this is merely for showing the structural relationship between the capacitor 180 and the conductive structures 140B and 140G. The conductive vias 160 are not electrically connected to the capacitor 180.

FIG. 18B is a circuit diagram of a semiconductor die in accordance with some embodiments. In greater detail, FIG. 18B is a circuit diagram of the semiconductor dies 100A and 100D of FIG. 18A. In some embodiments, when the semiconductor die 100A is a coupled inductor voltage regulators (CLVR), the circuit diagram of the semiconductor die 100A includes the transistor TR1, the transistor TR2, and the inductor 150. On the other hand, the semiconductor die 100D includes an inductor 150 and a capacitor 180. In some embodiments, the first end of the inductor 150 in the semiconductor die 100C is electrically connected to the first end of the inductor 150 in the semiconductor die 100A, and the second end of the inductor 150 in the semiconductor die 100C is electrically connected to the second end of the inductor 150 in the semiconductor die 100A. A first end of the capacitor 180 is electrically connected to the second end of the inductor 150 in the semiconductor die 100D, and a second end of the capacitor 180 is electrically connected to the ground terminal Vₛₛ.

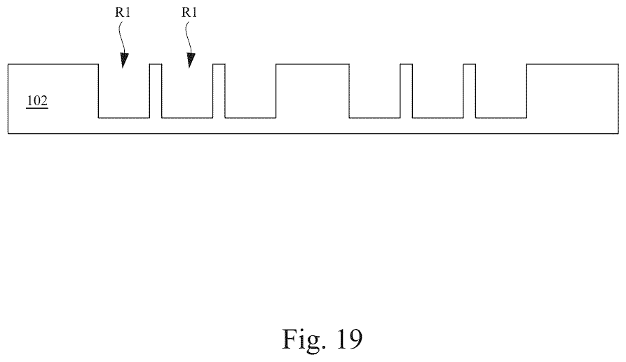

FIGS. 19 to 21 illustrate a method in various stages of forming a capacitor in accordance with some embodiments of the present disclosure. Specifically, FIGS. 19 to 21 illustrate a method for forming the capacitor 180 as shown in FIG. 18A. Accordingly, similar elements will be labeled the same, and relevant details will not be repeated for brevity. Although FIGS. 19 to 21 are described as a series of acts, it will be appreciated that these acts are not limiting in that the order of the acts can be altered in other embodiments, and the methods disclosed are also applicable to other structures. In other embodiments, some acts that are illustrated and/or described may be omitted in whole or in part.

Reference is made to FIG. 19. One or more trenches R1 are formed in the substrate 102. In some embodiments, the substrate 102 may be patterned using suitable photolithography and etching methods to form the trenches R1. For example, a photoresist (not shown) may be formed and patterned over the substrate 102, and one or more etching processes (e.g., a dry etch process) may be utilized to remove those portions of the substrate 102 where the trenches R1 are desired. As described below in greater detail the capacitor 180 will be formed in the trenches R1.

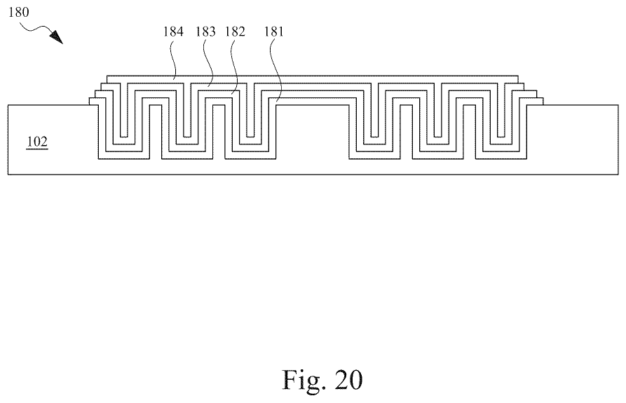

Reference is made to FIG. 20. A capacitor 180 is formed over the substrate 102 and filling the trenches R1 of the substrate 102. In some embodiments, a dielectric liner 181 is formed over the substrate 102 and along sidewalls and bottoms of the trenches R1. After forming the dielectric liner 181, capacitor electrodes 182 and 184 and capacitor dielectric layer 183 are formed sequentially in the trenches R1. In some embodiments, the dielectric liner 181, the capacitor electrodes 182 and 184, and the capacitor dielectric layer 183 may be patterned according to a predetermined pattern.

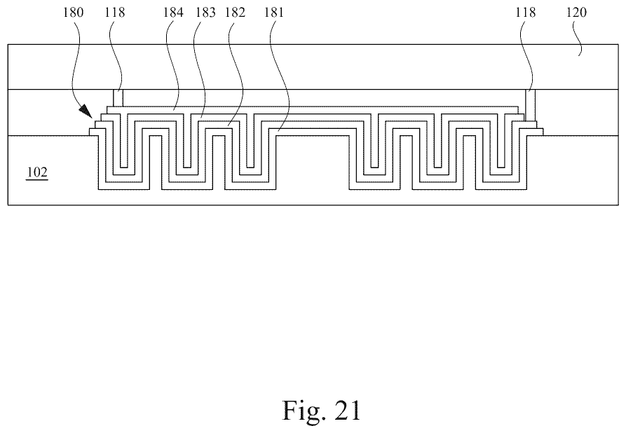

Reference is made to FIG. 21. An interlayer dielectric (ILD) layer 120 is formed over the substrate 102 and covering the capacitor 180. Afterwards, contacts 118 are formed in the ILD layer 120 and electrically connected to the capacitor 180.

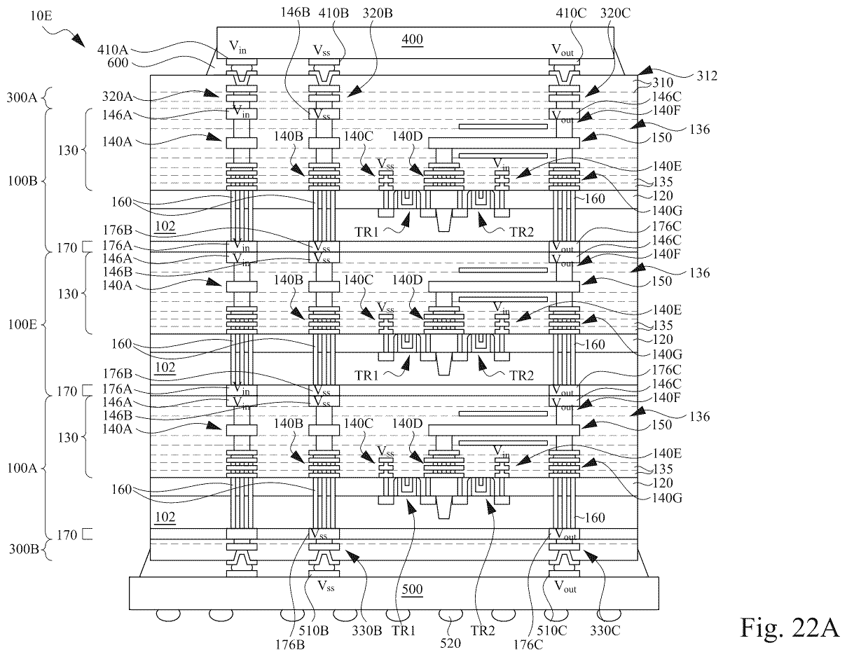

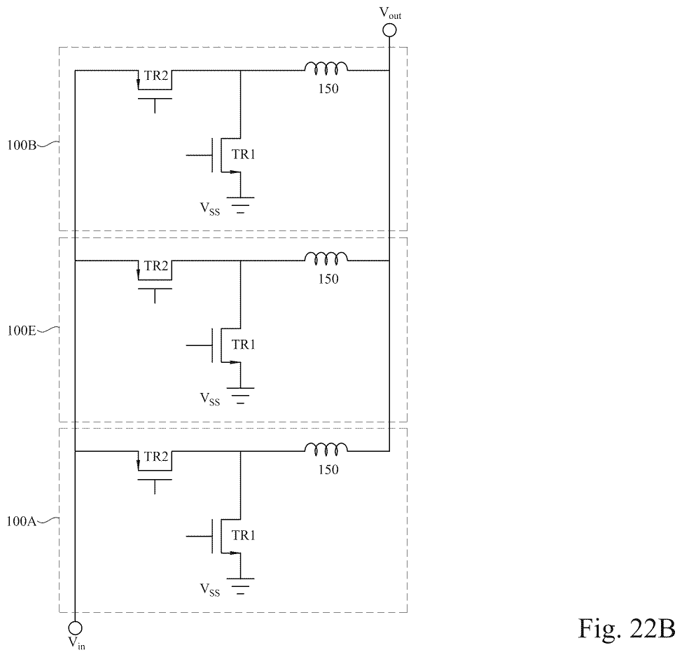

FIG. 22A is a cross-sectional view of a package structure in accordance with some embodiments. Shown there is a package structure 10E. It is noted that some elements in the package structure 10E of FIG. 22A are similar to those described with respect to the package structure 10B in FIG. 13A, such elements are labeled the same, and relevant details will not be repeated for brevity.

FIG. 22A is different from FIG. 13A, in that the package structure 10E further includes a semiconductor die 100E between the semiconductor die 100A and the semiconductor die 100B, in which the semiconductor die 100E may include substantially the same configuration as the semiconductor dies 100A and 100B. It is noted that the structural relationship between the semiconductor dies 100A and 100E is the same as the structural relationship between the semiconductor dies 100A and 100B as discussed in FIG. 13A, and the structural relationship between the semiconductor dies 100E and 100B is also the same as the structural relationship between the semiconductor dies 100A and 100B as discussed in FIG. 13A, and thus relevant details will not be repeated for brevity.

The formation method of the package structure 10E may include bonding the semiconductor die 100E to the semiconductor die 100A through hybrid bonding, and bonding the semiconductor die 100B to the semiconductor die 100E through hybrid bonding. Other structures in the package structure 10E can be formed once the stack of the semiconductor dies 100A, 100B, and 100E are bonded together.

FIG. 22B is a circuit diagram of a semiconductor die in accordance with some embodiments. In greater detail, FIG. 22B is a circuit diagram of the semiconductor dies 100A, 100E, and 100B of FIG. 22A. In some embodiments, when the semiconductor dies 100A, 100E, and 100B are coupled inductor voltage regulators (CLVRs), the circuit diagram of each the semiconductor dies 100A, 100E, and 100B includes the transistor TR1, the transistor TR2, and the inductor 150 as shown in FIG. 22A. In each of the semiconductor dies 100A, 100E, and 100B, the drain region of the transistor TR1 and the drain region of the transistor TR2 are electrically coupled with each other, and are electrically coupled to a first side of the inductor 150. Moreover, the input terminal Vᵢₙ is electrically connected to the source regions of the transistors TR2 of the semiconductor dies 100A, 100E, and 100B, the ground terminal Vₛₛ is electrically connected to the source regions of the transistors TR1 of the semiconductor dies 100A, 100E, and 100B, and the output terminal Vₒᵤₜ is electrically connected to second sides of the inductors 150 of the semiconductor dies 100A, 100E, and 100B.

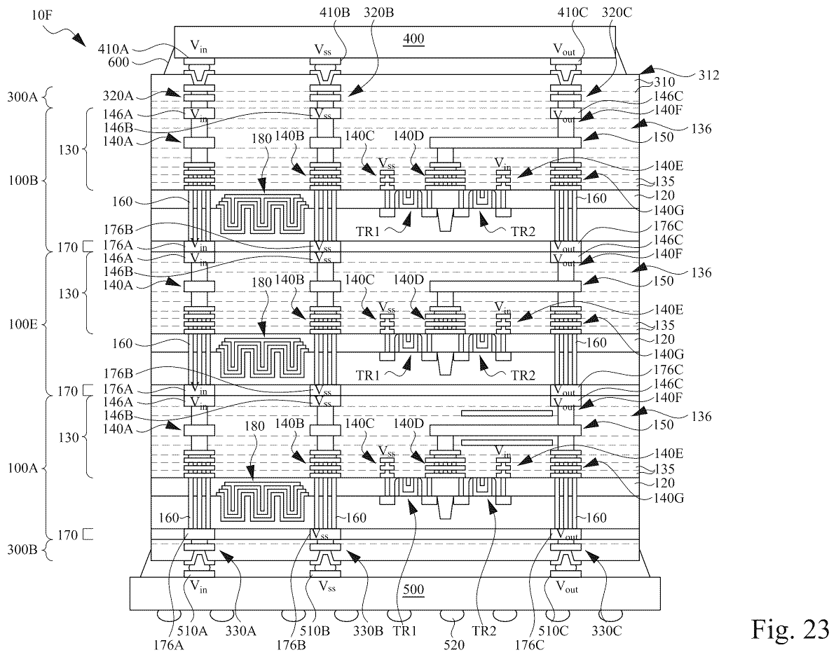

FIG. 23 is a cross-sectional view of a package structure in accordance with some embodiments. Shown there is a package structure 10F. It is noted that some elements in the package structure 10F of FIG. 23 are similar to those described with respect to the package structure 10E in FIG. 22A, such elements are labeled the same, and relevant details will not be repeated for brevity. FIG. 23 is different from FIG. 22A, in that each of the semiconductor dies 100A, 100B, and 100E of FIG. 23 further includes a capacitor 180 disposed on the substrate 102. In some embodiments, the capacitor 180 is located between the conductive structures 140A and 140B of the interconnect structure 130.

According to the aforementioned embodiments, it can be seen that the present disclosure offers advantages in fabricating integrated circuits. It is understood, however, that other embodiments may offer additional advantages, and not all advantages are necessarily disclosed herein, and that no particular advantage is required for all embodiments. Embodiments of the present disclosure provide a 3DIC structure with integrated voltage regulator. Embodiments of the present disclosure provide a 3DIC structure by stacking two or more voltage regulator dies through hybrid bonding, and shorting the input terminals, output terminals, and ground terminals of the voltage regulator dies. Embodiments of the present disclosure provide a 3DIC structure by stacking a voltage regulator die with a passive device die including discrete inductor and/or capacitor through hybrid bonding, and shorting the input terminals, output terminals, and ground terminals of the voltage regulator die and the passive device die. Embodiments of the present disclosure provide a 3DIC structure by stacking two or more voltage regulator dies through hybrid bonding, in which the voltage regulator dies may include other passive elements, such as capacitor. With such configuration, the inductance and capacitance in the 3DIC structure can be increased. The inductance voltage regular (IVR) current of the 3DIC structure can also be increased, for example, by 200%. Moreover, by integrating capacitor within the voltage regulator die can also reduce input and output ripple. Accordingly, the device performance may be improved.

In some embodiments of the present disclosure, a package structure includes a first semiconductor die, a first routing structure, a top die, a second routing structure, and a package substrate. The first semiconductor die includes a semiconductor substrate, a first transistor and a second transistor over the semiconductor substrate, a front side interconnect structure above first transistor and the second transistor, wherein the front side interconnect structure comprises a first inductor, wherein the first inductor is electrically coupled with source/drain regions of the first transistor and the second transistor, and a backside interconnect structure below the semiconductor substrate. The first routing structure is over and electrically connected to the first semiconductor die. The top die is over and electrically connected to the first routing structure. The second routing structure is below and electrically connected to the first semiconductor die. The package substrate is below and electrically connected to the second routing structure.

In some embodiments, the package structure further includes a second semiconductor die between the first semiconductor die and the first routing structure, wherein the second semiconductor die is bonded to the first semiconductor die through hybrid bonding.

In some embodiments, the first semiconductor die and the second semiconductor die comprise a same configuration.

In some embodiments, the second semiconductor die is free of an active device.

In some embodiments, the second semiconductor die includes a semiconductor substrate, a front side interconnect structure above the semiconductor substrate, wherein the front side interconnect structure comprises a second inductor, wherein a first side the second inductor is electrically coupled to a first side of the first inductor of the first semiconductor die, and a second side of the second inductor is electrically coupled to a second side of the first inductor of the first semiconductor die, and a backside interconnect structure below the semiconductor substrate.

In some embodiments, the front side interconnect structure of the second semiconductor die further comprises a capacitor electrically connected to the second side of the second inductor.

In some embodiments, the capacitor is a deep trench capacitor (DTC) structure, and at least a portion of the capacitor extends into the semiconductor substrate of the second semiconductor die.

In some embodiments of the present disclosure, a package structure includes a first semiconductor die, a second semiconductor die, a top die, and a package substrate. The first semiconductor die includes a first transistor and a second transistor, a first inductor, wherein a first side of the first inductor is electrically coupled with drain regions of the first transistor and the second transistor, a first input terminal electrically coupled to a source region of the second transistor, a first output terminal electrically coupled to a second side of the first inductor, and a first ground terminal electrically coupled to a source region of the first transistor. The second semiconductor die includes a third transistor and a fourth transistor, a second inductor, wherein a first side of the second inductor is electrically coupled with drain regions of the third transistor and the fourth transistor, a second input terminal electrically coupled to a source region of the fourth transistor and the first input terminal of the first semiconductor die, a second output terminal electrically coupled to a second side of the second inductor and the first output terminal of the first semiconductor die, and a second ground terminal electrically coupled to a source region of the third transistor and the first ground terminal of the first semiconductor die. The top die is over and electrically connected to the second semiconductor die. The package substrate is below and electrically connected to the first semiconductor die.

In some embodiments, the second semiconductor die stacking is connected to the first semiconductor through hybrid bonding.

In some embodiments, the first input terminal of the first semiconductor die comprises a first top input terminal at a top side of the first semiconductor die and a first bottom input terminal at a bottom side of the first semiconductor die, the first output terminal comprises a first top output terminal at the top side of the first semiconductor die and a first bottom output terminal at the bottom side of the first semiconductor die, and the first ground terminal comprises a first top ground terminal at the top side of the first semiconductor die and a first bottom ground terminal at the bottom side of the first semiconductor die, the second input terminal of the second semiconductor die comprises a second top input terminal at a top side of the second semiconductor die and a second bottom input terminal at a bottom side of the second semiconductor die, the second output terminal comprises a second top output terminal at the top side of the second semiconductor die and a second bottom output terminal at the bottom side of the second semiconductor die, and the second ground terminal comprises a second top ground terminal at the top side of the second semiconductor die and a second bottom ground terminal at the bottom side of the second semiconductor die, and the first top input terminal, the first top output terminal, and the first top ground terminal of the first semiconductor die are in contact with the second bottom input terminal, the second bottom output terminal, and the second bottom ground terminal of the second semiconductor die, respectively.

In some embodiments, the first top input terminal, the first top output terminal, and the first top ground terminal of the first semiconductor die are disposed in a first dielectric layer, and the second bottom input terminal, the second bottom output terminal, and the second bottom ground terminal of the second semiconductor die are disposed in a second dielectric layer, and wherein the first dielectric layer is in contact with the second dielectric layer.

In some embodiments, the first input terminal, the first output terminal, and the first ground terminal of the first semiconductor die vertically overlap with the second input terminal, the second output terminal, and the second ground terminal of the second semiconductor die, respectively.

In some embodiments, the package structure further includes a third semiconductor die between the first semiconductor die and the second semiconductor die. The third semiconductor die includes a fifth transistor and a sixth transistor, a third inductor, wherein a first side of the third inductor is electrically coupled with drain regions of the fifth transistor and the sixth transistor, a third input terminal electrically coupled to a source region of the sixth transistor, the first input terminal of the first semiconductor die, and the second input terminal of the second semiconductor die, a third output terminal electrically coupled to a second side of the third inductor, the first output terminal of the first semiconductor die, and the second output terminal of the second semiconductor die, and a third ground terminal electrically coupled to a source region of the fifth transistor, the first ground terminal of the first semiconductor die, and the second ground terminal of the second semiconductor die.

In some embodiments, the package structure further includes a first routing structure between and electrically connected to the second semiconductor die and the top die, and a second routing structure between and electrically connected to the first semiconductor die and the package substrate.

In some embodiments, one of the first semiconductor die and the second semiconductor die comprises a capacitor.

In some embodiments of the present disclosure, a method includes forming a first semiconductor die, comprising forming a first transistor and a second transistor over a semiconductor substrate; forming a first inductor above the first transistor and the second transistor, wherein a first side of the first inductor is electrically coupled with drain regions of the first transistor and the second transistor; bonding a second semiconductor die to the first semiconductor die through hybrid bonding; forming a first routing structure electrically connected to the second semiconductor die and a second routing structure electrically connected to the first semiconductor die; and bonding a top die to the first routing structure and a package substrate to the second routing structure.

In some embodiments, forming the first inductor comprises forming a lower magnetic layer; forming a conductor over the lower magnetic layer; and forming an upper magnetic layer over the conductor, wherein the lower magnetic layer is in contact with the upper magnetic layer, and the lower magnetic layer and the upper magnetic layer form a ring-shape structure surrounding the conductor in a cross-sectional view.

In some embodiments, forming the first semiconductor die further comprises forming a capacitor over the semiconductor substrate.

In some embodiments, the first semiconductor die and the second semiconductor die comprise a same configuration.

In some embodiments, the second semiconductor die is free of an active device.

The foregoing outlines features of several embodiments so that those skilled in the art may better understand the aspects of the present disclosure. Those skilled in the art should appreciate that they may readily use the present disclosure as a basis for designing or modifying other processes and structures for carrying out the same purposes and/or achieving the same advantages of the embodiments introduced herein. Those skilled in the art should also realize that such equivalent constructions do not depart from the spirit and scope of the present disclosure, and that they may make various changes, substitutions, and alterations herein without departing from the spirit and scope of the present disclosure.

What is claimed is:

1. A package structure, comprising:
a first semiconductor die, comprising:
a semiconductor substrate;
a first transistor and a second transistor over the semiconductor substrate;
a front side interconnect structure above first transistor and the second transistor, wherein the front side interconnect structure comprises a first inductor, wherein the first inductor is electrically coupled with source/drain regions of the first transistor and the second transistor; and
a backside interconnect structure below the semiconductor substrate;
a first routing structure over and electrically connected to the first semiconductor die;
a top die over and electrically connected to the first routing structure;
a second routing structure below and electrically connected to the first semiconductor die; and
a package substrate below and electrically connected to the second routing structure.

2. The package structure of claim 1, further comprising a second semiconductor die between the first semiconductor die and the first routing structure, wherein the second semiconductor die is bonded to the first semiconductor die through hybrid bonding.

3. The package structure of claim 2, wherein the first semiconductor die and the second semiconductor die comprise a same configuration.

4. The package structure of claim 2, wherein the second semiconductor die is free of an active device.

5. The package structure of claim 4, wherein the second semiconductor die comprises:
a semiconductor substrate;
a front side interconnect structure above the semiconductor substrate, wherein the front side interconnect structure comprises a second inductor, wherein a first side the second inductor is electrically coupled to a first side of the first inductor of the first semiconductor die, and a second side of the second inductor is electrically coupled to a second side of the first inductor of the first semiconductor die; and
a backside interconnect structure below the semiconductor substrate.

6. The package structure of claim 5, wherein the front side interconnect structure of the second semiconductor die further comprises a capacitor electrically connected to the second side of the second inductor.

7. The package structure of claim 6, wherein the capacitor is a deep trench capacitor (DTC) structure, and at least a portion of the capacitor extends into the semiconductor substrate of the second semiconductor die.

8. A package structure, comprising:
a first semiconductor die, comprising:
a first transistor and a second transistor;
a first inductor, wherein a first side of the first inductor is electrically coupled with drain regions of the first transistor and the second transistor;
a first input terminal electrically coupled to a source region of the second transistor;
a first output terminal electrically coupled to a second side of the first inductor; and
a first ground terminal electrically coupled to a source region of the first transistor;
a second semiconductor die stacking over the first semiconductor, comprising:
a third transistor and a fourth transistor;
a second inductor, wherein a first side of the second inductor is electrically coupled with drain regions of the third transistor and the fourth transistor;
a second input terminal electrically coupled to a source region of the fourth transistor and the first input terminal of the first semiconductor die;
a second output terminal electrically coupled to a second side of the second inductor and the first output terminal of the first semiconductor die; and
a second ground terminal electrically coupled to a source region of the third transistor and the first ground terminal of the first semiconductor die;
a top die over and electrically connected to the second semiconductor die; and
a package substrate below and electrically connected to the first semiconductor die.

9. The package structure of claim 8, wherein the second semiconductor die stacking is connected to the first semiconductor through hybrid bonding.

10. The package structure of claim 8, wherein,
the first input terminal of the first semiconductor die comprises a first top input terminal at a top side of the first semiconductor die and a first bottom input terminal at a bottom side of the first semiconductor die, the first output terminal comprises a first top output terminal at the top side of the first semiconductor die and a first bottom output terminal at the bottom side of the first semiconductor die, and the first ground terminal comprises a first top ground terminal at the top side of the first semiconductor die and a first bottom ground terminal at the bottom side of the first semiconductor die,
the second input terminal of the second semiconductor die comprises a second top input terminal at a top side of the second semiconductor die and a second bottom input terminal at a bottom side of the second semiconductor die, the second output terminal comprises a second top output terminal at the top side of the second semiconductor die and a second bottom output terminal at the bottom side of the second semiconductor die, and the second ground terminal comprises a second top ground terminal at the top side of the second semiconductor die and a second bottom ground terminal at the bottom side of the second semiconductor die, and
the first top input terminal, the first top output terminal, and the first top ground terminal of the first semiconductor die are in contact with the second bottom input terminal, the second bottom output terminal, and the second bottom ground terminal of the second semiconductor die, respectively.

11. The package structure of claim 10, wherein the first top input terminal, the first top output terminal, and the first top ground terminal of the first semiconductor die are disposed in a first dielectric layer, and the second bottom input terminal, the second bottom output terminal, and the second bottom ground terminal of the second semiconductor die are disposed in a second dielectric layer, and wherein the first dielectric layer is in contact with the second dielectric layer.

12. The package structure of claim 8, wherein the first input terminal, the first output terminal, and the first ground terminal of the first semiconductor die vertically overlap with the second input terminal, the second output terminal, and the second ground terminal of the second semiconductor die, respectively.

13. The package structure of claim 8, further comprising:
a third semiconductor die between the first semiconductor die and the second semiconductor die, comprising:
a fifth transistor and a sixth transistor;
a third inductor, wherein a first side of the third inductor is electrically coupled with drain regions of the fifth transistor and the sixth transistor;
a third input terminal electrically coupled to a source region of the sixth transistor, the first input terminal of the first semiconductor die, and the second input terminal of the second semiconductor die;
a third output terminal electrically coupled to a second side of the third inductor, the first output terminal of the first semiconductor die, and the second output terminal of the second semiconductor die; and
a third ground terminal electrically coupled to a source region of the fifth transistor, the first ground terminal of the first semiconductor die, and the second ground terminal of the second semiconductor die.

14. The package structure of claim 8, further comprising:
a first routing structure between and electrically connected to the second semiconductor die and the top die; and
a second routing structure between and electrically connected to the first semiconductor die and the package substrate.

15. The package structure of claim 8, wherein one of the first semiconductor die and the second semiconductor die comprises a capacitor.

16. A method, comprising:
forming a first semiconductor die, comprising:
forming a first transistor and a second transistor over a semiconductor substrate;
forming a first inductor above the first transistor and the second transistor, wherein a first side of the first inductor is electrically coupled with drain regions of the first transistor and the second transistor;
bonding a second semiconductor die to the first semiconductor die through hybrid bonding;
forming a first routing structure electrically connected to the second semiconductor die and a second routing structure electrically connected to the first semiconductor die; and
bonding a top die to the first routing structure and a package substrate to the second routing structure.

17. The method of claim 16, wherein forming the first inductor comprises:
forming a lower magnetic layer;
forming a conductor over the lower magnetic layer; and
forming an upper magnetic layer over the conductor, wherein the lower magnetic layer is in contact with the upper magnetic layer, and the lower magnetic layer and the upper magnetic layer form a ring-shape structure surrounding the conductor in a cross-sectional view.

18. The method of claim 16, wherein forming the first semiconductor die further comprises:
forming a capacitor over the semiconductor substrate.

19. The method of claim 16, wherein the first semiconductor die and the second semiconductor die comprise a same configuration.

20. The method of claim 16, wherein the second semiconductor die is free of an active device.
